(19) United States
(12) Patent Application Publication
(10) Pub. No.: US 2026/0273687 A1
(43) Pub. Date: Sep. 17, 2026

(54) POLISHING APPARATUS, SUBSTRATE PROCESSING APPARATUS, POLISHING METHOD, AND DETERMINATION DEVICE

(71) Applicant: EBARA CORPORATION, Tokyo (JP)

(72) Inventors: Masaki KINOSHITA, Tokyo (JP); Ji Chul YANG, Tokyo (JP)

(21) Appl. No.: 19/562,438

(22) Filed: Mar. 10, 2026

(30) Foreign Application Priority Data
Mar. 12, 2025 (JP) 2025-039585

(51) Int. Cl. B24B 37/005; B24B 37/10; H10P 52/40

(52) U.S. Cl. CPC B24B 37/005; B24B 37/107; H10P 52/402

(57) ABSTRACT

Particles that damage a substrate are detected more efficiently or more precisely. A polishing apparatus includes a detector that performs detection of a signal related to at least one of a size, shape, dispersibility, and optical property of particles, from a polishing liquid positioned on a polishing surface, or the polishing liquid positioned in a flow path or a chamber that communicates with a pad opening portion formed in a polishing pad, and a control device is configured to perform particle determination to determine whether the polishing liquid on which the detection is performed contains particles that damage the substrate, based on particle data indicating at least one of the size, shape, dispersibility, and optical property of particles obtained based on the signal detected by the detector, and correspondence information indicating correspondence of the size of the particle of the polishing liquid, and whether the particles are the particles that damage the substrate.

### TECHNICAL FIELD

The present invention relates to a polishing apparatus, a substrate processing apparatus, a polishing method, and a determination device. This application claims priority from Japanese Patent Application No. 2025-039585 filed on Mar. 12, 2025. The entire disclosure including the descriptions, the claims, the drawings, and the abstract in Japanese Patent Application No. 2025-039585 is herein incorporated by reference.

### BACKGROUND ART

In the manufacturing process of semiconductor devices, techniques for planarizing semiconductor device surfaces are becoming increasingly important. As the planarizing techniques, there is known chemical mechanical polishing (CMP). The chemical mechanical polishing uses a polishing apparatus to perform polishing by sliding a substrate such as a semiconductor wafer in contact with a polishing pad while supplying a polishing liquid (slurry) containing abrasive particles such as silica (SiO₂) and/or ceria (CeO₂) to the polishing pad.

If the polishing liquid contains agglomerates of abrasive particles, foreign matter or the like, polishing may not be performed as expected, or the surface of the substrate may be scratched to cause damage to the substrate. Patent Literature 1 discloses a polishing apparatus that irradiates the wafer polishing surface of a wafer with ultrasonic waves during polishing, measures the slurry particle size, monitors the variation in slurry particle size, and transmits an output signal to a chemical liquid supply control unit when a change occurs in the particle size distribution profile. Patent Literature 2 discloses that in the polishing method, the sampled slurry is filtered, and foreign matter on the surface of the filtration membrane is observed by using a scanning electron microscope or the like.

### CITATION LIST

### Patent Literature

PTL 1: Japanese Patent Lait-Open No. 2004-363229
PTL 2: Japanese Patent Laid-Open No. 2008-145102

### SUMMARY OF INVENTION

### Technical Problem

In the polishing apparatus of Patent Literature 1, the state of the wafer polishing surface may change during measurement of the particle size distribution. Furthermore, Patent Literature 1 does not perform determination based on the sizes of the particles in the particle size distribution. In Patent Literature 2, the state of the slurry may change while the slurry is being collected and prepared for observation.

An object of the present invention, which has been made in view of the aforementioned circumstances, is to provide a determination device, a polishing apparatus, a substrate processing apparatus, or a polishing method that can evaluate a state of a polishing liquid more efficiently or more precisely while suppressing change in the state of the polishing liquid, concerning the polishing liquid after being served on a polishing surface.

### Solution to Problem

According to one embodiment of the present invention, a polishing apparatus is a polishing apparatus including a polishing table for supporting a polishing pad having a polishing surface, a polishing head for holding a substrate, a polishing liquid supply device for supplying a polishing liquid to between the polishing pad and the substrate, and a control device, and performing polishing of the substrate by bringing the polishing pad and the substrate into contact with each other in presence of the polishing liquid, and the polishing apparatus further includes a detector that performs detection of a signal related to at least one of a size, shape, dispersibility, and optical property of particles, from the polishing liquid positioned on the polishing surface, or the polishing liquid positioned in a flow path or a chamber that communicates with a pad opening portion formed in the polishing pad, wherein the control device is configured to perform particle determination to determine whether the polishing liquid on which the detection has been performed contains particles that damage the substrate, based on particle data indicating at least one of the size, shape, dispersibility, and optical property of the particles obtained based on the signal detected by the detector, and correspondence information indicating correspondence of at least one of the size, shape, dispersibility, and optical property of particles of the polishing liquid, and whether the particles are the particles that damage the substrate.

According to another embodiment of the present invention, a polishing method is a polishing method for performing polishing of a substrate by bringing a polishing pad and the substrate into contact with each other in presence of a polishing liquid by a polishing apparatus including a polishing table for supporting the polishing pad having a polishing surface, a polishing head for holding the substrate, and a polishing liquid supply device for supplying the polishing liquid to between the polishing pad and the substrate, and includes performing detection of a signal related to at least one of a size, shape, dispersibility, and an optical property of particles, from the polishing liquid positioned on the polishing surface, or the polishing liquid positioned in a flow path or a chamber that communicates with a pad opening portion formed in the polishing pad, and performing particle determination to determine whether the polishing liquid on which the detection has been performed contains particles that damage the substrate, based on particle data indicating the size of the particles obtained based on the signal detected by a detector, and correspondence information indicating correspondence of at least one of the size, shape, dispersibility, and optical property of particles of the polishing liquid, and whether the particles are the particles that damage the substrate.

According to another embodiment of the present invention, a determination device is a determination device that determines a state of a polishing liquid in a polishing apparatus, wherein the polishing apparatus includes a polishing table for supporting a polishing pad having a polishing surface, a polishing head for holding a substrate, and a polishing liquid supply device for supplying the polishing liquid to between the polishing pad and the substrate, and performs polishing of the substrate by bringing the polishing pad and the substrate into contact with each other in presence of the polishing liquid, the polishing apparatus further includes a detector that performs detection of a signal related to at least one of a size, shape, dispersibility, and optical property of particles, from the polishing liquid positioned on the polishing surface, or the polishing liquid positioned in a flow path or a chamber that communicates with a pad opening portion formed in the polishing pad, and the determination device is configured to perform particle determination to determine whether the polishing liquid on which the detection has been performed contains particles that damage the substrate, based on particle data indicating at least one of the size, shape, dispersibility, and optical property of the particles obtained based on the signal detected by the detector, and correspondence information indicating correspondence of at least one of the size, shape, dispersibility, and optical property of the particles of the polishing liquid, and whether the particles are the particles that damage the substrate.

### BRIEF DESCRIPTION OF DRAWINGS

FIG. 1 is a schematic view showing an entire configuration of a substrate processing apparatus according to one embodiment.

FIG. 2 is a perspective view schematically showing a configuration of a polishing apparatus according to one embodiment.

FIG. 3 is a sectional view of the polishing apparatus schematically showing a particle detection system of the polishing apparatus.

FIG. 4 is a schematic view showing detection of particles by the particle detection system.

FIG. 5A is an enlarged plan view of a polishing pad schematically showing an example of a pad opening portion.

FIG. 5B is an enlarged plan view of a polishing pad schematically showing another example of the pad opening portion.

FIG. 6A is an enlarged plan view of a polishing table schematically showing an example of a table opening portion.

FIG. 6B is an enlarged plan view of a polishing table schematically showing another example of the table opening portion.

FIG. 7 is a flowchart showing a flow of a polishing method according to one embodiment.

FIG. 8 is a sectional view of a polishing apparatus schematically showing a particle detection system according to modification 1.

FIG. 9 is a sectional view of a polishing apparatus schematically showing a particle detection system according to modification 2-1.

FIG. 10 is a sectional view of a polishing apparatus schematically showing a particle detection system according to modification 2-2.

FIG. 11 is a sectional view of a polishing apparatus schematically showing a particle detection system according to modification 2-3.

FIG. 12 is a sectional view of a polishing apparatus schematically showing a particle detection system according to modification 2-4.

FIG. 13 is a sectional view of a polishing apparatus schematically showing a particle detection system according to modification 3-1.

FIG. 14 is a sectional view of a polishing apparatus schematically showing a particle detection system according to modification 3-2.

FIG. 15 is a sectional view of a polishing apparatus schematically showing a particle detection system according to modification 3-3.

FIG. 16 is a sectional view of a polishing apparatus schematically showing a particle detection system according to modification 3-4.

FIG. 17 is a sectional view of a polishing apparatus schematically showing a particle detection system according to modification 3-5.

FIG. 18 is a sectional view of a polishing apparatus schematically showing a particle detection system according to modification 3-6.

FIG. 19 is a plan view of a polishing pad schematically showing an example of disposition of a pad opening portion according to modification 4.

FIG. 20 is a sectional view of a polishing apparatus schematically showing a configuration of a particle detection system according to modification 5.

FIG. 21 is a sectional view of a polishing apparatus schematically showing a configuration of a particle detection system according to modification 6.

### DESCRIPTION OF EMBODIMENTS

Hereinafter, embodiments of the present invention will be described with the accompanying drawings. In the accompanying drawings, the same or similar elements are denoted by the same or similar reference signs, and duplicate explanations of the same or similar elements may be omitted in the explanation of each embodiment. Furthermore, features shown in each embodiment are applicable to other embodiments unless they are mutually inconsistent.

In the present description, “substrate” includes not only semiconductor substrates, glass substrates, liquid crystal substrates, and printed circuit boards, but also magnetic recording media, magnetic recording sensors, mirrors, optical elements, micromechanical devices, or partially fabricated integrated circuit, and any other object to be processed. The substrate may be of any shape including a polygonal shape and a circular shape.

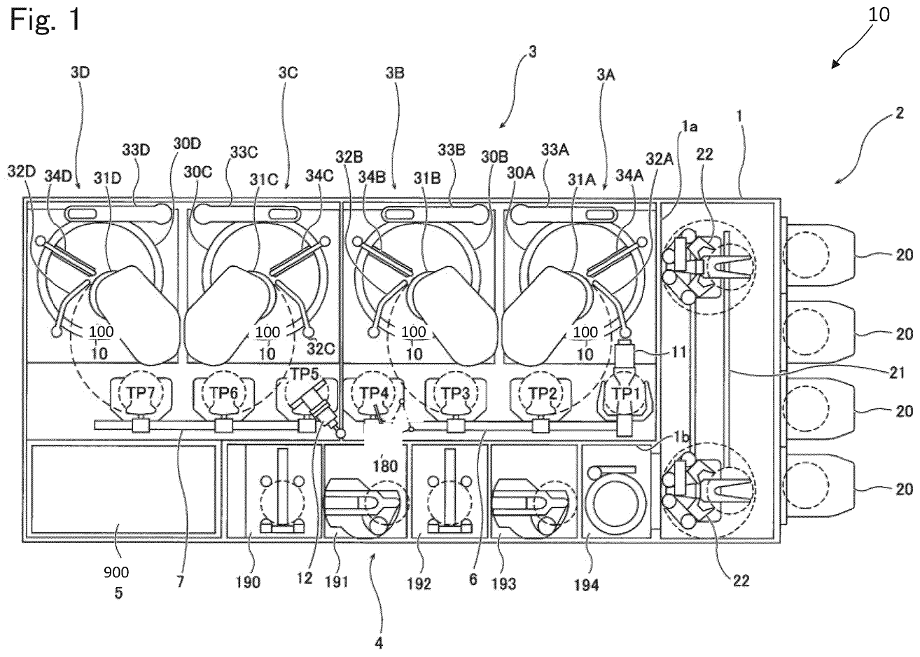

FIG. 1 is a plan view showing one embodiment of a substrate processing apparatus. A substrate processing apparatus 10 is implemented as a semiconductor manufacturing apparatus and includes a housing 1 in a substantially rectangular shape as shown in FIG. 1, and an interior of the housing 1 is divided into a load/unload unit 2, a polishing unit 3, and a cleaning unit 4 by partition walls 1a and 1b. The load/unload unit 2, the polishing unit 3, and the cleaning unit 4 are respectively assembled independently, and vented independently. Furthermore, the substrate processing apparatus 10 includes a control device 900 that controls a substrate processing operation.

The load/unload unit 2 includes two or more (four in the present embodiment) front load sections 20 on which wafer cassettes that stock a large number of substrates (wafers) are placed. The front load sections 20 are arranged adjacent to the housing 1 and are arranged along a width direction (direction perpendicular to a longitudinal direction) of the substrate processing apparatus 10. On the front load section 20, an open cassette, an SMIF (Standard Manufacturing Interface) pod, or an FOUP (Front Opening Unified Pod) can be mounted.

Furthermore, in the load/unload unit 2, a traveling mechanism 21 is laid along arrangement of the front load sections 20, and two transport robots (loaders, transport mechanisms) 22 that are movable along an arrangement direction of the wafer cassettes are installed on the traveling mechanism 21. The transport robots 22 can have access to the wafer cassettes mounted on the front load sections 20 by moving on the traveling mechanism 21.

The polishing unit 3 is a region where polishing (flattening) of substrates is performed, and includes a first polishing unit 3A, a second polishing unit 3B, a third polishing unit 3C, and a fourth polishing unit 3D. The first polishing unit 3A, the second polishing unit 3B, the third polishing unit 3C, and the fourth polishing unit 3D are arranged along the longitudinal direction of the substrate processing apparatus 10 as shown in FIG. 1.

As shown in FIG. 1, the first polishing unit 3A includes a polishing table 30A to which a polishing pad 100 having a polishing surface is attached, a polishing head 31A for polishing while holding a substrate and pressing the substrate against the polishing pad 100 on the polishing table 30A, a polishing liquid supply device 32A for supplying a polishing liquid and a dressing liquid (for example, pure water) to between the polishing pad 100 and the substrate, a dresser 33A for dressing the polishing surface of the polishing pad 100, and an atomizer 34A that atomizes a mixture fluid of a liquid (for example, pure water) and gas (for example, nitrogen gas) or liquid (for example, pure water) to inject it to the polishing surface.

Likewise, the second polishing unit 3B includes a polishing table 30B, a polishing head 31B, a polishing liquid supply device 32B, a dresser 33B, and an atomizer 34B. The third polishing unit 3C includes a polishing table 30C, a polishing head 31C, a polishing liquid supply device 32C, a dresser 33C, and an atomizer 34C. The fourth polishing unit 3D includes a polishing table 30D, a polishing head 31D, a polishing liquid supply device 32D, a dresser 33D, and an atomizer 34D.

Next, a transport mechanism for transporting a substrate will be described. As shown in FIG. 1, a first linear transporter 6 is arranged adjacent to the first polishing unit 3A and the second polishing unit 3B. The first linear transporter 6 is a mechanism that transports a substrate among four transport positions (defined as a first transport position TP1, a second transport position TP2, a third transport position TP3, and a fourth transport position TP4 in order from a load/unload unit side) along a direction in which the polishing units 3A and 3B are arranged.

Furthermore, a second linear transporter 7 is arranged adjacent to the third polishing unit 3C and the fourth polishing unit 3D. The second linear transporter 7 is a mechanism that transports a substrate among three transport positions (defined as a fifth transport position TP5, a sixth transport position TP6, and a seventh transport position TP7 in order from the load/unload unit side) along a direction in which the polishing units 3C and 3D are arranged.

A substrate is transported to the polishing units 3A and 3B by the first linear transporter 6. The polishing head 31A of the first polishing unit 3A moves between a polishing position and the second transport position TP2 by a swinging motion. Accordingly, transfer of a substrate to the polishing head 31A is performed at the second transport position TP2.

Likewise, the polishing head 31B of the second polishing unit 3B moves between a polishing position and the third transport position TP3, and transfer of a substrate to the polishing head 31B is performed at the third transport position TP3. The polishing head 31C of the third polishing unit 3C moves between a polishing position and the sixth transport position TP6, and transfer of a substrate to the polishing head 31C is performed at the sixth transport position TP6. The polishing head 31D of the fourth polishing unit 3D moves between a polishing position and the seventh transport position TP7, and transfer of the substrate to the polishing head 31D is performed at the seventh transport position TP7.

A lifter 11 for receiving a substrate from the transport robot 22 is arranged at the first transport position TP1. The substrate is transferred from the transport robot 22 to the first linear transporter 6 via the lifter 11. A shutter (not illustrated) is provided at the partition wall 1a to be positioned between the lifter 11 and the transport robot 22, and during transport of a substrate, the shutter is opened so that the substrate is transferred from the transport robot 22 to the lifter 11.

A swing transporter 12 is arranged among the first linear transporter 6, the second linear transporter 7, and the cleaning unit 4. The swing transporter 12 has a hand that is movable between the fourth transport position TP4 and the fifth transport position TP5, and transfer of a substrate from the first linear transporter 6 to the second linear transporter 7 is performed by the swing transporter 12. The substrate is transported to the third polishing unit 3C and/or the fourth polishing unit 3D by the second linear transporter 7. Furthermore, the substrate that is polished in the polishing unit 3 is transported to the cleaning unit 4 via the swing transporter 12.

The cleaning unit 4 includes a first substrate cleaning device 190, a second substrate cleaning device 192, a substrate drying device 194, and transport robots 191 and 193 for performing transfer of a substrate between these devices. The substrate on which polishing processing is performed in the polishing unit 3 is cleaned (primary cleaning) in the first substrate cleaning device 190 and is subsequently further cleaned (final cleaning) in the second substrate cleaning device 192. The substrate after being cleaned is transferred into the substrate drying device 194 from the second substrate cleaning device 192 and spin-dried. The substrate after being dried is returned to the load/unload unit 2. Note that the configuration of the substrate processing apparatus 10 is not particularly limited if only particle detection described later can be performed in the following embodiment.

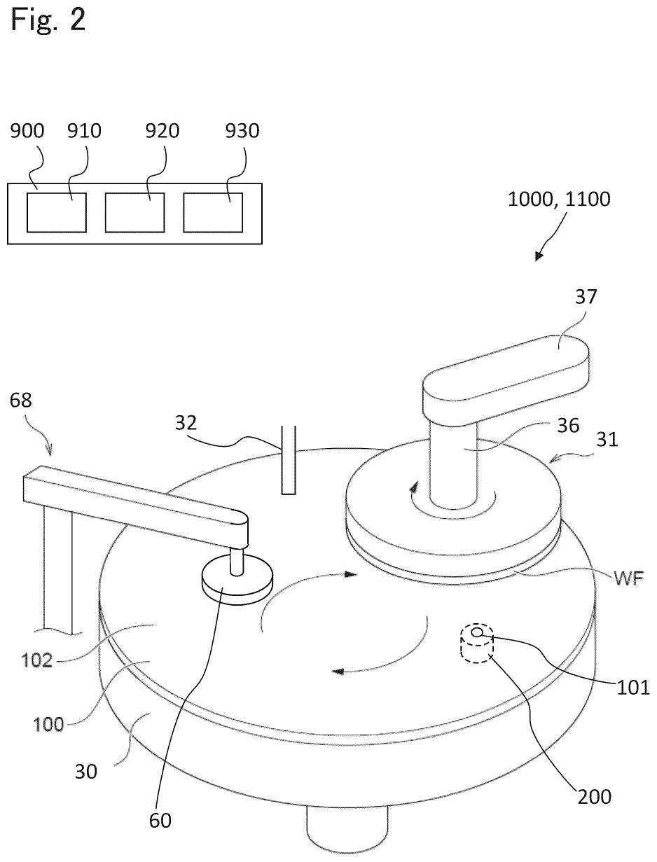

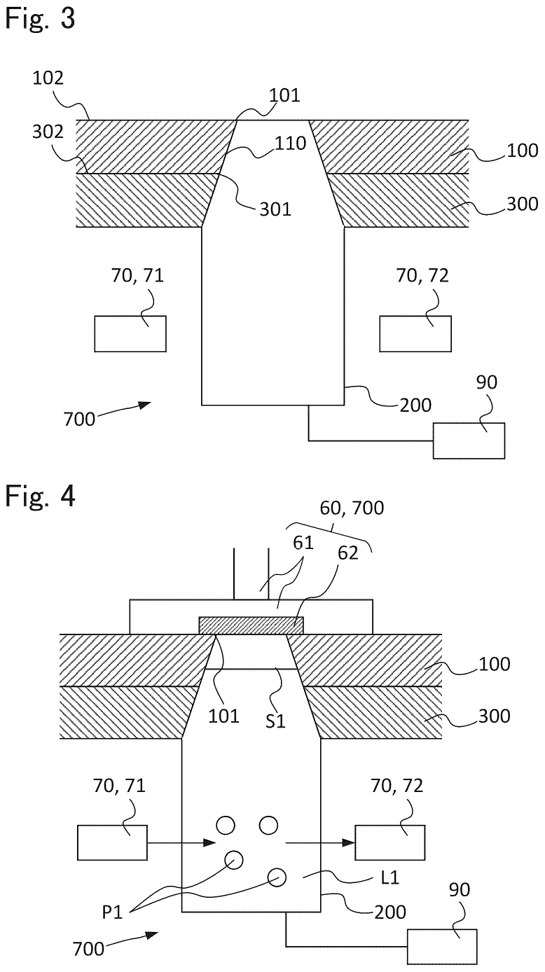

FIG. 2 is a perspective view showing a schematic configuration of the polishing apparatus according to the present embodiment. A polishing apparatus 1000 can constitute at least one of the aforementioned polishing unit 3. The polishing apparatus 1000 and the polishing pad 100 constitute a polishing system 1100. The polishing apparatus 1000 of the present embodiment is configured to be able to perform polishing of a substrate WF in a disk shape such as a semiconductor wafer as an object to be polished by using the polishing pad 100 having a polishing surface 102. As illustrated, the polishing apparatus 1000 includes a polishing table 30 for supporting the polishing pad 100 in the disk shape, and a polishing head 31 for holding the substrate WF to press it against the polishing surface 102 of the polishing pad 100. The polishing apparatus 1000 performs polishing of the substrate WF by bringing the polishing pad 100 and the substrate WF into contact with each other in presence of a polishing liquid. Furthermore, the polishing apparatus 1000 includes a movable member 60, and a polishing liquid supply device 32, a dresser, and an atomizer (omitted in FIG. 3) that are described above. The movable member 60 is configured to be movable by a drive mechanism 68 and is driven so as not to contact the polishing head 31 and the polishing liquid supply device 32. As described later, the movable member 60 may be a dresser, or a different member from the dresser. The drive mechanism 68 can include a rotating mechanism, a linear actuator or the like, including a motor.

The polishing apparatus 1000 includes the control device 900 for controlling each part of the polishing apparatus 1000 such as a particle detection system described later. The control device 900 includes at least one information processing device such as an ordinary computer or an exclusive computer. At least a part of data that is processed in the control device 900 may be stored in a remote server or the like. The control device 900 includes an arithmetic unit 910, a memory 920, and a storage device 930. The arithmetic unit 910 includes a processor such as a central processing unit (CPU). The storage device 930 includes a nonvolatile storage medium such as a solid state drive, and can store a program that performs control or the like of the particle detection system. The program may be acquired by obtaining the program recorded in a recording medium such as DVD-ROM, or may be acquired via a network. The arithmetic unit 910 performs various processes by reading the program stored in the storage device 930 or the like in the memory 920 and executing it. Note that the physical configuration and the like of the control device 900 are not limited if only control by the control device 900 is possible.

The polishing table 30 is formed in a disk shape and is configured to be rotatable with a center axis thereof as a rotation axial line. The polishing pad 100 is attached to the polishing table 30 by pasting or the like. A surface of the polishing pad 100 forms the polishing surface 102. The polishing pad 100 rotates integrally with the polishing table 30 by the polishing table 30 rotating by a motor not illustrated. In this way, the polishing apparatus 1000 is configured to perform polishing of the substrate WF by bringing the polishing pad 100 and the substrate WF into contact with each other and rotationally moving them relative to each other in presence of the polishing liquid. Note that the polishing table 30 is not limited to the disk shape, but may be in a rectangular shape, for example. In this case, the polishing pad 100 that is wound in a roll shape may be configured to be fed out to the polishing table 30.

The polishing head 31 holds the substrate WF by vacuum suction and the like on an undersurface thereof. The polishing head 31 is configured to be rotatable with the substrate WF by power from a motor not illustrated. An upper portion of the polishing head 31 is connected to a support arm 37 via a shaft 36. The polishing head 31 is movable in an up-down direction by motor drive via an air cylinder or a ball screw not illustrated, and a distance from the polishing table 30 is adjustable. Accordingly, the polishing head 31 can press the held substrate WF against the polishing surface 102. Furthermore, the polishing head 31 has an air bag divided into a plurality of regions, in an inside thereof though not illustrated, and presses the substrate WF from a rear surface by supplying pressure of any fluid such as air to each of the air bag regions. Furthermore, the support arm 37 is configured to be turnable by a motor not illustrated, and moves the polishing head 31 in a direction parallel to the polishing surface 102. In the present embodiment, the polishing head 31 is configured to be movable between a position where the substrate is received and the position above the polishing pad 100, and is configured to be able to change a position where the substrate WF is pressed against the polishing pad 100.

As shown in FIG. 2, in the present embodiment, a pad opening portion 101 that opens in the polishing surface 102 is formed in the polishing pad 100. The polishing table 30 includes a chamber 200 that communicates with the pad opening portion 101. The polishing table 30 is configured so that the polishing liquid located in the polishing pad 100 is introduced into the chamber 200 through the pad opening portion 101.

FIG. 3 is a schematic sectional view showing the particle detection system according to the present embodiment. FIG. 3 corresponds to a sectional view of the polishing apparatus 1000 perpendicular to the polishing surface 102. Each of sectional views as follows also shows a section of the polishing apparatus perpendicular to the polishing surface 102. The polishing apparatus 1000 includes a particle detection system 700, and the particle detection system 700 includes a measurement unit 70, and the chamber 200 in which the polishing liquid is accommodated. In the present embodiment, the polishing pad 100 includes a through-hole 110 that passes through the pad opening portion 101, and penetrates from the polishing surface 102 to a surface on an opposite side of the polishing surface 102. The polishing table 30 includes a pad disposing surface 302 on which the polishing pad 100 is placed, and an upper member 300 that defines the pad disposing surface 302. A table opening portion 301 is formed in the pad disposing surface 302. The table opening portion 301 is in fluid communication with the chamber 200 that is arranged on a lower side of the polishing surface 102, in other words, an opposite side to a side where the polishing pad 100 is positioned, with respect to the table opening portion 301. When polishing of the substrate WF is performed, the polishing pad 100 is placed on the polishing table 30 so that the pad opening portion 101 is in fluid communication with the chamber 200 through the through-hole 110. In other words, the polishing pad 100 is placed so that the pad opening portion 101 and the table opening portion 301 communicate with each other, or the pad opening portion 101 and the table opening portion 301 overlap each other along the pad disposing surface 302.

The measurement unit 70 is configured to acquire a signal concerning a size of particles included in the polishing liquid accommodated in the chamber 200 by measurement. In the present embodiment, it is determined whether the polishing liquid contains particles that damage the substrate WF as described later. The type of particles is not particularly limited, and may be agglomerates of abrasive particles, fragments of the substrate WF or polishing pad 100, or foreign matter or the like that is mingled. A method for measuring the size of particles is not particularly limited, and measurement can be performed by a laser diffraction/scattering method, dynamic light scattering method, ultrasonic attenuation method, zeta potential measurement, spectroscopic measurement, or analysis of an image obtained by capturing the image of the polishing liquid. From the viewpoint of precisely detecting the particles of the size that damages the substrate WF in the polishing liquid, it is preferable to perform measurement by a dynamic light scattering method. Furthermore, any two or more of these measurement methods may be combined. For example, a wider range of particle diameters may be measured by performing measurement using both the laser diffraction/scattering method, and dynamic light scattering method. Alternatively, a plurality of types of measurements may be performed, and when it is determined that the polishing liquid does not contain particles that damage the substrate WF for all the measurements, the final determination may be that the polishing liquid does not contain particles that damage the substrate WF.

As shown in FIG. 3, the measurement unit 70 can include an irradiation device 71, and a detector 72. The irradiation device 71 can include a laser light source or a visible light source, or an ultrasonic source such as a transducer, depending on the measurement method. The detector 72 can include a photodetector including a photomultiplier tube, a photodiode or the like, or an ultrasonic detector such as a transducer, depending on the measurement method. Hereinafter, detection of a signal related to at least one of a size, shape, dispersibility, and optical property of particles from the polishing liquid by the detector 72 will be referred to as particle detection. In the present embodiment, the detector 72 performs detection of a signal related to the size of the particles from the polishing liquid. The signal related to the size of the particles is a signal from which particle data indicating the size of the particles can be acquired by analyzing the signal. The signal related to the size of the particles is, for example, light in the optical measurement, sound waves in the ultrasonic attenuation method, and visible light when analyzing a polishing liquid image. The particle data can include, for example, a particle diameter, an amount of particles having that diameter, and the like. The irradiation device 71 is configured to irradiate a polishing liquid L1 with electromagnetic waves or ultrasonic waves for the purpose of particle detection.

In the present embodiment, the irradiation device 71 and the detector 72 are positioned below the pad disposing surface 302. Accordingly, since the irradiation device 71 and the detector 72 are not positioned in a region above the polishing surface 102, more components can be arranged in that region. Furthermore, the detector 72 is configured to perform detection of a signal related to the size of the particles from the polishing liquid L1 that is positioned in the chamber 200 that communicates with the pad opening portion 101. By the configuration like this, it is possible to more reliably introduce the polishing liquid L1 into the chamber 200 by using gravity. Furthermore, it is possible to quickly perform particle detection with respect to the polishing liquid L1 located on the polishing surface 102, and it is possible to perform particle detection more efficiently, or more precisely by suppressing change in the state of the polishing liquid L1. Furthermore, since the chamber 200 extends more downward than the table opening portion 301, an adverse effect on the particle detection due to variation in the thickness by the different polishing pads 100 can be reduced more than in the case in which the polishing liquid L1 is located in only the polishing pad 100 described later. Further, polishing conditions are easily adjusted, by blocking light from an outside or the like of the polishing apparatus 1000, and the like. Furthermore, as compared with the case of irradiating the wafer polishing surface on the wafer with ultrasonic waves as in Patent Literature 1, detection can be performed more precisely.

FIG. 4 is a sectional view schematically showing the particle detection system 700 when it is performing particle detection. The detector 72 of the present embodiment performs detection of the signal related to the size of the particles from the polishing liquid L1 that is positioned in the chamber 200. The chamber 200 functions as a polishing liquid accommodation section that accommodates the polishing liquid L1 for the purpose of particle detection. The chamber 200 may be a measuring cell. The chamber 200 is formed by a wall having translucency or has a window portion not illustrated and having translucency, and light that is emitted from the irradiation device 71 is incident on the polishing liquid L1 in the chamber 200. The light incident on the polishing liquid L1 is scattered or reflected by particles P1 in the polishing liquid L1, or passes through the polishing liquid L1 and is incident on the detector 72. The detection signal obtained by detection of the signal related to the size of the particles P1 by the detector 72 is appropriately converted into analog/data (A/D) to be outputted to the control device 900 or the like, or is analyzed in the detector 72, and the obtained particle data is outputted to the control device 900 or the like. In the illustrated example, a liquid level S1 of the polishing liquid L1 is positioned at a same height as the polishing pad 100, but an amount of the polishing liquid L1 that is introduced into the chamber 200 is not particularly limited if only particle detection can be performed with desired precision. When particle detection is performed during polishing, it is preferable that the liquid level S1 is flush with the polishing surface 102 or in a vicinity of the polishing surface 102 in order to suppress uneven polishing. Note that FIG. 3 shows disposition of a transmission type in which the irradiation device 71 and the detector 72 are on opposite sides with the chamber 200 therebetween, but the irradiation device 71 and the detector 72 may be integrated, or on a same side. Furthermore, side detectors for capturing light that is scattered or reflected at any angle may be arranged, depending on the measurement method. In this way, the detector 72 can perform detection of electromagnetic waves or ultrasonic waves that are irradiated from the irradiation device 71 and pass through the polishing liquid L1, or electromagnetic waves or ultrasonic waves that are generated by scattering or reflection of the irradiated electromagnetic waves or ultrasonic waves in the polishing liquid L1.

As shown in FIG. 4, the particle detection system 700 may include the movable member 60. The movable member 60 is configured to be movable between an upper side of the polishing surface 102, and a retraction position at a side of the polishing table 30. In the present embodiment, the movable member 60 includes a movable member body 61, and a light blocking member 62. The light blocking member 62 is a member that absorbs or reflects light, such as a light blocking plate. As described above, the movable member 60 may be a dresser, and since in this case, the number of members in the region on the upper side of the polishing surface 102 decreases, more members can be arranged in that region. The control device 900 stops rotation of the polishing table 30, and can move the movable member 60 to cover the pad opening portion 101 by the movable member 60, when performing particle detection. In this way, the movable member 60 can be a shutter for blocking light from the pad opening portion 101. Accordingly, noise in the particle detection is reduced, and particle detection can be more accurately performed. Alternatively, the polishing liquid L1 may be selectively introduced from the pad opening portion 101 to the chamber 200 or the like, and the amount of the polishing liquid L1 that is introduced may be adjusted, by the movable member 60. In this way, the movable member 60 may be a shutter for preventing inflow of the polishing liquid L1 from the pad opening portion 101. The shape of the movable member 60, and the material or the like of the light blocking member 62 are not particularly limited if only particle detection can be performed with desired precision, and, for example, the movable member 60 may be shaped like a lid.

Note that when measurement methods other than the optical measurement are used, or when light from the pad opening portion 101 is weak enough to allow particle detection with desired precision, the particle detection system 700 may not include the movable member 60. This configuration is suitable for performing particle detection while performing polishing of the substrate WF.

As shown in FIG. 3 and FIG. 4, the particle detection system 700 may include a pump 90. The pump 90 is connected to the chamber 200 to be capable of suction. By suction of the pump 90, it is possible to promote introduction of the polishing liquid L1 into the chamber 200 from the polishing surface 102, and discharge of the polishing liquid L1 from the chamber 200, and it is possible to more reliably perform particle detection. Note that if the polishing liquid L1 can be introduced into the chamber 200 by gravity or operation of the polishing head 31 that moves across the pad opening portion 101, the particle detection system 700 may not include the pump 90.

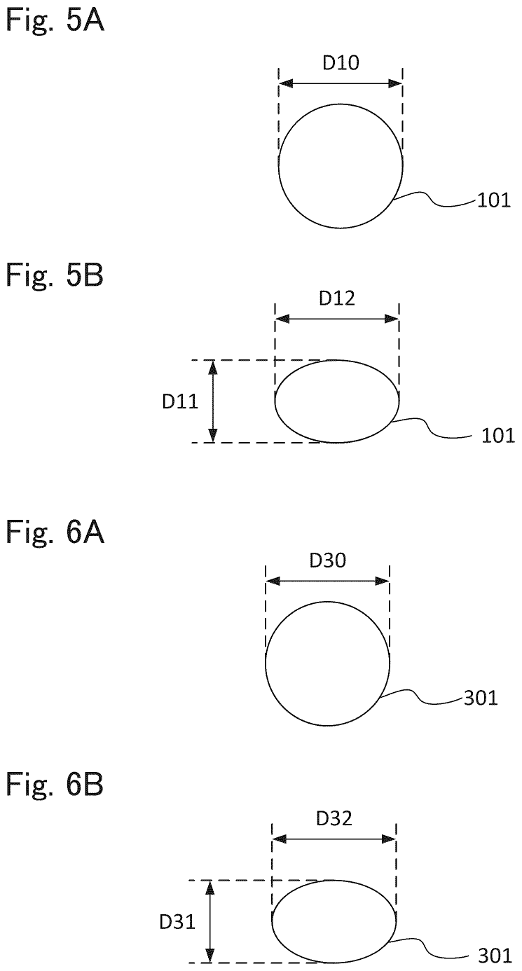

FIG. 5A is a plan view schematically showing an example of the shape of the pad opening portion 101. As shown in FIG. 5A, the pad opening portion 101 preferably has a circular shape. Further, the through-hole 110 (FIG. 3) preferably has a circular shape in a section that is perpendicular to the flow path. By the configuration like this, when compared at a same sectional area, a length or an area where the polishing liquid L1 contacts the pad opening portion 101 or the through-hole 110 is small, and resistance when the polishing liquid L1 flowing can be reduced. From a viewpoint of making it easy to introduce the polishing liquid L1, a diameter D10 of the pad opening portion 101 is preferably 1 mm or more. Since the pad opening portion 101 that is too large can adversely affect efficiency or uniformity of polishing, the diameter D10 of the pad opening portion 101 is preferably 10 mm or less. In this way, the polishing system 1100 (FIG. 1) of the present embodiment includes the polishing apparatus 1000, and the polishing pad 100, and the diameter D10 of the polishing pad 100 is preferably 1 mm or more and 10 mm or less.

FIG. 5B is a plan view schematically showing another example of the shape of the pad opening portion 101. As shown in FIG. 5B, the pad opening portion 101 may have an elliptical shape. The shape of the pad opening portion 101 is not particularly limited if only the polishing liquid L1 can be introduced into the chamber 200 through the pad opening portion 101. From a viewpoint of making it easy to introduce the polishing liquid L1, a minimum diameter D11 of the pad opening portion 101 is preferably 1 mm or more. Since the pad opening portion 101 that is too large may adversely affect efficiency or uniformity of polishing, a maximum diameter D12 of the pad opening portion 101 is preferably 10 mm or less.

FIG. 6A is a plan view schematically showing an example of a shape of the table opening portion 301. As shown in FIG. 6A, the table opening portion 301 preferably has a circular shape. Accordingly, when compared at a same sectional area, a length where the polishing liquid L1 contacts is small, and resistance when the polishing liquid L1 flowing can be reduced. From a viewpoint of making it easy to introduce the polishing liquid L1, a diameter D30 of the table opening portion 301 is preferably 1 mm or more. Since the table opening portion 301 that is too large may adversely affect efficiency or uniformity of polishing, the diameter D30 of the table opening portion 301 is preferably 10 mm or less.

FIG. 6B is a plan view schematically showing another example of the shape of the table opening portion 301. As shown in FIG. 6B, the table opening portion 301 may have an elliptical shape. The shape of the table opening portion 301 is not particularly limited if only the polishing liquid L1 can be introduced into the chamber 200 through the table opening portion 301. From a viewpoint of making it easy to introduce the polishing liquid L1, a minimum diameter D31 of the table opening portion 301 is preferably 1 mm or more. Since the table opening portion 301 that is too large may adversely affect efficiency or uniformity of polishing, a maximum diameter D32 of the table opening portion 301 is preferably 10 mm or less.

In FIG. 3, the through-hole 110 of the polishing pad 100, and a portion of the polishing table 30 that connects the through-hole 110 and the chamber 200 are each in a shape of a truncated cone that tapers upward, or toward a side on which the polishing pad 100 is placed, but are not limited to this, and may be in a cylindrical shape, or a shape of a truncated cone that tapers downward or toward a chamber 200 side.

As shown in FIG. 2, the pad opening portion 101 is preferably positioned so that the substrate WF covers the pad opening portion 101 at least temporarily, or the pad opening portion 101 passes below the substrate WF, when the substrate WF contacts the polishing surface 102 and polishing is performed, in the polishing pad 100. In other words, the polishing pad 100 is preferably placed on the pad disposing surface 302 so that the pad opening portion 101 is positioned at the position like this. Accordingly, polishing dust and the like generated by polishing of the substrate WF can be efficiently detected. From a same viewpoint, the table opening portion 301 is preferably positioned so that the substrate WF covers the table opening portion 301 at least temporarily, or the table opening portion 301 passes below the substrate WF, when the substrate WF contacts the polishing surface 102 and polishing is performed, in the polishing table 30.

The control device 900 (FIG. 2) is configured to determine whether the polishing liquid L1 on which particle detection has been performed contains the particles that damage the substrate WF, based on the particle data obtained in the particle detection. The determination is referred to as particle determination. In the particle determination, determination is performed based on the particle data, and correspondence information. The correspondence information is information indicating correspondence of at least one of the size, shape, dispersibility, and optical property of the particles P1 of the polishing liquid L1, and whether the particles P1 are the particles that damage the substrate WF. In the present embodiment, the correspondence information is the information indicating the correspondence of the size of the particles P1 of the polishing liquid L1, and whether the particles P1 are the particles that damage the substrate WF. The correspondence information may include only threshold values, or the threshold values may be associated with various polishing conditions, types of polishing liquids, or the like. The correspondence information may be stored in the storage device 930 in advance or may be acquired from a remote server or the like by communication. In this way, the control device 900 can be a determination device that determines the state of the polishing liquid L1 in the polishing apparatus 1000.

The control device 900 acquires the particle data. The control device 900 receives the detection signal obtained by detection of the signal related to the size of the particles P1, of the detector 72, and generates the particle data indicating the size of the particles P1 contained in the polishing liquid L1, by an algorithm corresponding to the measurement method. Alternatively, the control device 900 receives the particle data generated in the detector 72.

In the particle determination, it may be determined whether the polishing liquid L1 contains particles that damage the substrate WF, based on the sizes of the particles P1 indicated by the particle data, and the threshold value included in the correspondence information. For example, the particle data may include particle size distribution data indicating the amount of the particles P1 of a predetermined size contained in the polishing liquid L1. In the particle size distribution data, a bin is set for particle diameters in each fixed range, and numeral values of the particle diameters corresponding to the bin, and an amount or a proportion of the particles P1 with the particle diameters in the range of that bin may be linked. When the correspondence information includes only a threshold value, the control device 900 can determine, based on the particle data, that the polishing liquid L1 contains particles that damage the substrate WF, when the polishing liquid L1 contains the particles P1 with a particle diameter equal to or larger than the threshold value at a predetermined rate or more. A numeral value of this predetermined rate may be included in the correspondence information. When the polishing liquid L1 contains the particles P1 with a particle diameter equal to or larger than the threshold value at a rate less than the predetermined rate, the control device 900, based on the particle data, can determine that the polishing liquid L1 does not contain the particles that damage the substrate WF. Alternatively, the particle data may include statistical values indicating the sizes of the particles P1, such as an arithmetic mean of the particle diameters of the particles P1 contained in the polishing liquid L1. As for such statistical values, suitable statistical values can be selected depending on the measurement method. In this case, when the statistical value is equal to or larger than the threshold value included in the correspondence information, the control device 900 may determine that the polishing liquid L1 contains particles that damage the substrate WF, and when the statistical value is less than the threshold value, the control device 900 may determine that the polishing liquid L1 does not contain the particles that damage the substrate WF.

When the control device 900 determines that the polishing liquid L1 contains the particles that may damage the substrate WF by the particle determination, the control device 900 can perform at least one of cleaning of the polishing surface 102 and displaying warning on a display device or the like not illustrated. In cleaning of the polishing surface 102, for example, dressing of the polishing surface 102 can be performed by the dresser. When it is determined that the polishing liquid L1 contains the particles that damage the substrate WF by the particle determination during polishing, the control device 900 preferably stops polishing. When it is determined that the polishing liquid L1 contains the particles that damage the substrate WF by the particle determination when polishing is not being performed, execution of polishing may not be permitted. In the warning, text, graphics, or the like is used to indicate that there is an abnormality in the polishing liquid L1, that inspection of the flow path of the polishing liquid supply device 32 is recommended, that replacement of the polishing pad 100 is recommended, or the like. Note that warning may be performed by sound.

As above, in the present embodiment, the control device 900 is configured to perform at least one of issuing of warning, stop of polishing, and cleaning of the polishing surface 102, when the control device 900 determines that the polishing liquid L1 on which particle detection has been performed contains the particles that damage the substrate WF, by the particle determination. Accordingly, it is possible to prevent the substrate WF from being damaged or prevent polishing that is different from what is expected from being performed.

When determining that the polishing liquid L1 contains the particles that damage the substrate WF, the control device 900 may determine whether or not to perform cleaning of the polishing surface 102 based on the particle data and the correspondence information. In this case, when a degree of the abnormality of the polishing liquid L1 is large, and cannot be restored by cleaning of the polishing surface 102 such as dressing, the control device 900 may issue only warning or the like without performing cleaning of the polishing surface 102. For example, the correspondence information can include a first threshold value, and a second threshold value larger than the first threshold value. When the statistical value indicating the size of the particles such as a mean value of the particle diameters, which is included in the particle data, is smaller than the first threshold value, the control device 900 can determine that the polishing liquid L1 does not contain the particles that damage the substrate WF. When the statistical value is larger than the first threshold value and smaller than the second threshold value, the control device 900 determines that the polishing liquid L1 contains the particles that damage the substrate WF, and can start cleaning of the polishing surface 102. When the statistical value is larger than the second threshold value, the control device 900 determines that the polishing liquid L1 contains the particles that damage the substrate WF, and can perform display of warning or the like without performing cleaning of the polishing surface 102. Note that determination using the correspondence information is not limited to the aforementioned method, and the threshold value can be made different according to the polishing conditions and the like, for example. Furthermore, the control device 900 may set conditions of cleaning of the polishing surface 102 based on the particle data and the correspondence information. For example, when the degree of abnormality in the polishing liquid L1 is large based on the threshold value or the like included in the correspondence information, the control device 900 can extend the dressing time or can increase the amount of liquid that is used during dressing.

The control device 900 can perform particle detection and particle determination when the polishing liquid L1 is supplied to the polishing pad 100. Accordingly, it is possible to precisely determine the state of the supplied polishing liquid L1. The control device 900 may perform particle detection and particle determination while performing polishing. Accordingly, when the state of the polishing liquid L1 or the polishing pad 100 is worsened during polishing, it is possible to detect worsening, and prevent the substrate WF from being damaged, or polishing that is different from what is expected from being performed. Alternatively, the control device 900 can perform particle detection and particle determination when the polishing liquid L1 remains on the polishing pad after end of polishing. Accordingly, cleaning of the polishing surface 102, replacement of the polishing pad 100, or the like is performed before restart of polishing, and it is possible to prevent the substrate WF from being damaged in restarted polishing, and polishing that is different from what is expected from being performed.

As described above, particle detection and acquisition of particle data are performed by at least one of a laser diffraction/scattering method, dynamic light scattering method, ultrasonic attenuation method, zeta potential measurement, spectroscopic measurement, and analysis of an image obtained by capturing an image of the polishing liquid L1. Accordingly, it is possible to more reliably detect the particles that damage the substrate WF in the polishing liquid L1, by taking advantage of the characteristics of each of the measurement methods.

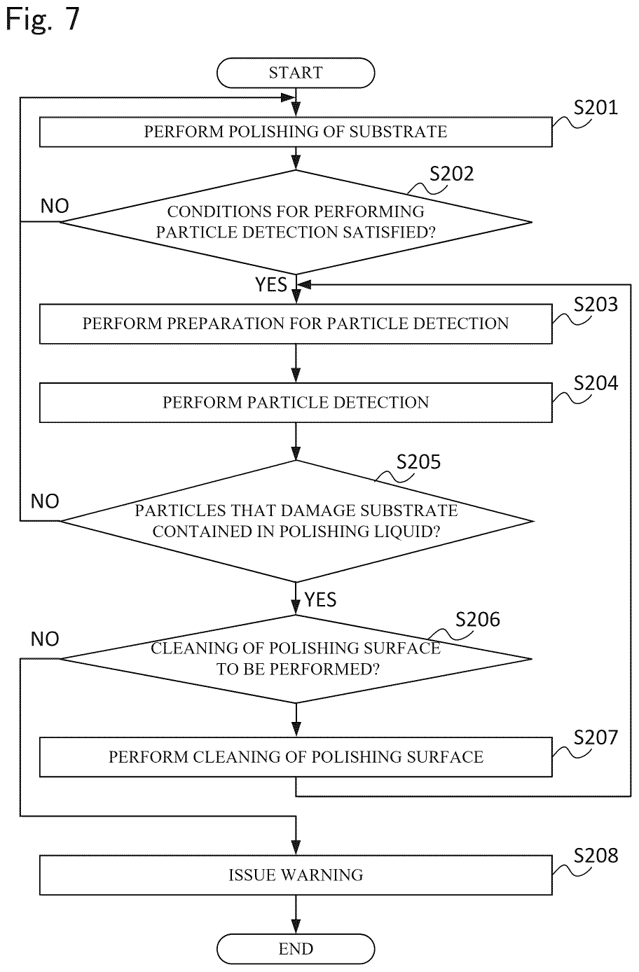

FIG. 7 is a flowchart showing a flow of a polishing method of the present embodiment. The polishing method can be executed by the arithmetic unit 910 and the like of the control device 900. In step S201, the control device 900 controls the polishing table 30, the polishing head 31, the polishing liquid supply device 32 and the like and performs polishing of the substrate WF. After step S201, step S202 is performed. In step S202, the control device 900 determines whether or not the conditions for performing particle detection are satisfied. For example, the control device 900 can perform particle detection after performing polishing of a predetermined number of substrates WF. The predetermined number is not particularly limited, and can be, for example, 100, or the like. When the control device 900 determines that the conditions for performing particle detection are satisfied, the control device 900 starts step S203. When the control device 900 determines that the conditions for performing particle detection are not satisfied, the control device 900 starts step S201.

In step S203, the control device 900 performs preparation for particle detection. For example, the control device 900 performs suction by the pump 90 as necessary, and introduces the polishing liquid L1 into the chamber 200. When particle detection is performed by covering the pad opening portion 101 with the movable member 60, the control device 900 stops rotation of the polishing table 30, and performs control to move the movable member 60 so that it covers the pad opening portion 101. After step S203, step S204 is performed. In step S204, the control device 900 controls the measurement unit 70 to perform particle detection. After step S204, step S205 is performed.

In step S205, the control device 900 performs determination (particle determination) of whether the polishing liquid L1 contains the particles that damage the substrate WF. When the control device 900 determines that the polishing liquid L1 contains the particles that may damage the substrate WF in the particle determination, the control device 900 starts step S206. In this case, when the particle determination is performed during polishing, polishing is stopped. When the control device 900 determines that the polishing liquid L1 does not contain the particles that damage the substrate WF in the particle determination, the control device 900 starts step S201.

In step S206, the control device 900 determines whether or not to perform cleaning of the polishing surface 102. The control device 900 may make this determination based on the particle data and the correspondence information as described above or may make this determination based on input of a user. When the control device 900 performs cleaning of the polishing surface 102, the control device 900 starts step S207. When the control device 900 does not perform cleaning of the polishing surface 102, the control device 900 starts step S208.

In step S207, the control device 900 performs cleaning of the polishing surface 102. The control device 900 controls the dresser, and can perform dressing or the like of the polishing surface 102. After step S207, step S203 is performed. In step S208, the control device 900 issues a warning. After the warning, investigation of the cause of abnormality in the polishing liquid L1, replacement of consumables, or the like is performed by the user of the polishing apparatus 1000.

In the polishing method of the present embodiment, the polishing apparatus 1000 performs detection (particle detection) of the signal related to the size of the particles P1 from the polishing liquid L1 positioned in the chamber 200 that communicates with the pad opening portion 101, and determines whether the polishing liquid L1 on which the particle detection is performed contains the particles that damage the substrate WF, based on the particle data indicating the size of the particles P1 obtained based on the signal detected by the detector 72, and the correspondence information indicating the correspondence of the size of the particles P1 of the polishing liquid L1, and whether the particles are the particles that damage the substrate WF. Accordingly, it is possible to evaluate the state of the polishing liquid L1 more efficiently, or more precisely while suppressing change in the state of the polishing liquid L1, concerning the polishing liquid L1 after being served on the polishing surface 102.

### Modification 1

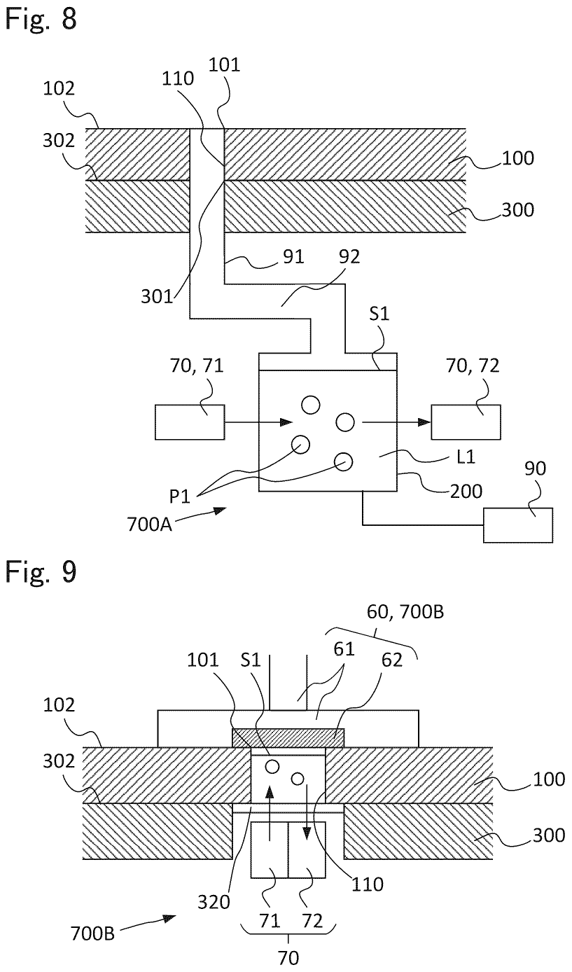

FIG. 8 is a schematic view showing a particle detection system 700A according to the present modification. The particle detection system 700A according to the present modification has a substantially same configuration as the particle detection system 700 according to the aforementioned embodiment, but differs in that it includes piping 91 between a table opening portion 301 and a chamber 200. The piping 91 defines a flow path 92 that passes through an inside thereof. The flow path 92 fluidly connects the table opening portion 301 and the chamber 200. A polishing pad 100 is placed so that a through-hole 110 is fluidly connected to the flow path 92. In other words, the polishing pad 100 is placed so that the through-hole 110 and the flow path 92 overlap each other along a pad disposing surface 302. A polishing liquid L1 on a polishing surface 102 is introduced into the chamber 200 through the through-hole 110 and the flow path 92, and particle detection is performed on the introduced polishing liquid L1. Introduction of the polishing liquid L1 into the chamber 200 is preferably promoted by suction by a pump 90. In the present modification, a measurement unit 70 and the chamber 200 can be positioned inside a polishing table 30. In the present modification, the particle detection system 700 may include a movable member 60. However, in the present modification, it is possible to make it difficult for light from the pad opening portion 101 to reach the position of the polishing liquid L1 when particle detection is performed. In this case, the particle detection system 700A may not include the movable member 60 that covers the pad opening portion 101.

In the present modification, the polishing apparatus 1000 includes the flow path 92 that fluidly connects the table opening portion 301 and the chamber 200. Accordingly, it is possible to make it difficult for the light from the pad opening portion 101 to reach the chamber 200, and it is possible to precisely perform particle detection by optical measurement without covering the pad opening portion 101. Furthermore, since the measurement unit 70 and the chamber 200 can be arranged in various positions, it is possible to increase the degree of freedom in design. Furthermore, the polishing apparatus 1000 of the present modification includes the pump 90 connected to the flow path 92 or the chamber 200 to be able to suck the flow path 92. Accordingly, it is possible to more reliably move the polishing liquid L1 to the chamber 200 that is the detection position.

Note that the particle detection system 700A may not include the chamber 200, and the measurement unit 70 may be installed around the piping 91 that defines the flow path 92 that fluidly communicates with the table opening portion 301 to perform particle detection on the polishing liquid L1 that is positioned in the flow path 92. Accordingly, it is possible to more compactly constitute the particle detection system 700A and further increase the degree of freedom in design. The polishing apparatus 1000 can be configured to include at least one of the aforementioned flow path 92 and chamber 200.

### Modification 2-1

FIG. 9 is a sectional view of a polishing table 30 schematically showing a particle detection system 700B according to the present modification. The particle detection system 700B according to the present modification differs from the particle detection system 700 of the aforementioned embodiment in that it has a table window portion 320 instead of the aforementioned table opening portion 301, and a measurement unit 70 is arranged to be able to perform particle detection on a polishing liquid L1 located between the table window portion 320 and a pad opening portion 101.

In an upper member 300 of the polishing table 30, the table window portion 320 that defines a pad disposing surface 302 of the polishing table 30 is formed. An irradiation device 71 and a detector 72 are preferably arranged on an opposite side to a side where a polishing pad 100 is placed, with respect to the table window portion 320. In other words, the irradiation device 71 and the detector 72 are preferably positioned below the table window portion 320. In the present modification, particle detection is performed on a polishing liquid L1 that is positioned in a through-hole 110 of the polishing pad 100. The irradiation device 71 is configured to irradiate the polishing liquid L1 with electromagnetic waves or ultrasonic waves through the table window portion 320. The detector 72 is configured to detect a signal of an electromagnetic wave, an ultrasonic wave or the like that passes through the table window portion 320 from the polishing liquid L1. Note that the table window portion 320 may be arranged at a position that is offset downward from the pad disposing surface 302. Since in the case of the present modification, there is a possibility that reflection light from a light blocking member 62 may affect the precision of particle detection, the light blocking member 62 is preferably selected appropriately from those with high light absorption properties, according to the measurement methods.

A polishing method of the present modification is carried out as follows. The polishing pad 100 is placed on the polishing table 30 so that the table window portion 320 and the pad opening portion 101 overlap each other along the pad disposing surface 302. Thereafter, the polishing liquid L1 is introduced into the through-hole 110 by gravity or an action of a polishing head 31 that moves on a polishing surface 102, the pad opening portion 101 is appropriately blocked by a movable member 60, and particle detection is performed on the polishing liquid L1 introduced into the through-hole 110. In the present modification, the detector 72 is configured to perform detection of a signal related to a size of particles P1 from the polishing liquid L1 that is positioned in the through-hole 110 formed in the polishing pad 100. Accordingly, it is possible to suppress reduction in efficiency or uniformity of polishing due to the table opening portion 301. Note that a polishing apparatus 1000 may further include a film thickness measurement instrument not illustrated that includes an optical sensor or an eddy current sensor, and the film thickness measurement instrument may be arranged below the table window portion 320.

### Modification 2-2

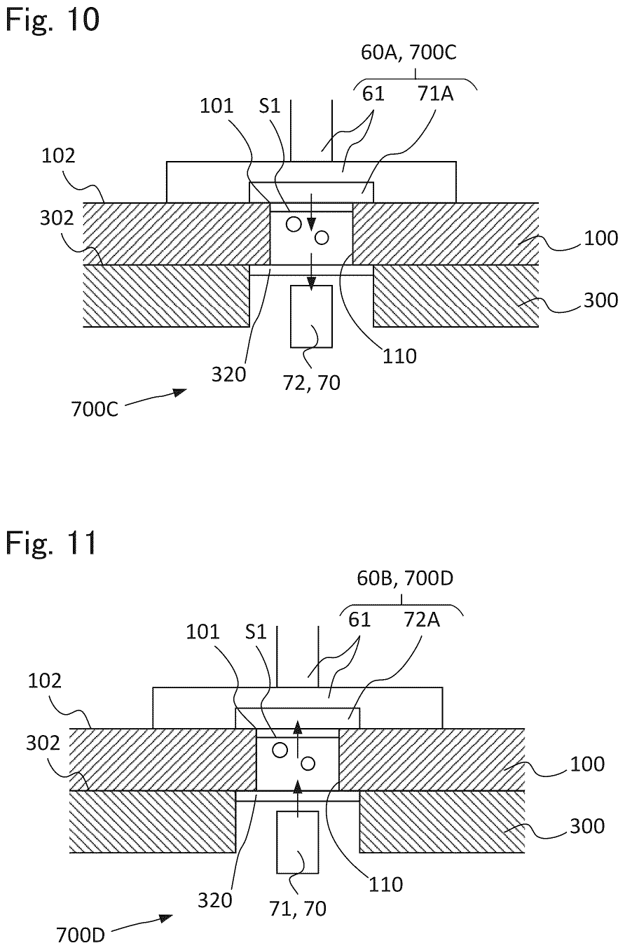

FIG. 10 is a sectional view schematically showing a particle detection system 700C according to the present modification. The particle detection system 700C according to the present modification differs from the particle detection system 700B of modification 2-1 described above in that it includes a movable member 60A instead of the movable member 60, and includes an irradiation device 71A instead of the irradiation device 71. The movable member 60A includes the irradiation device 71A and is configured so that the irradiation device 71A irradiates a polishing liquid L1 located between a table window portion 320 and a pad opening portion 101 with electromagnetic waves or the like. Signals such as electromagnetic waves from the polishing liquid L1 are detected by a detector 72 arranged below the table window portion 320.

In the present modification, the movable member 60A includes the irradiation device 71A that irradiates the polishing liquid L1 with electromagnetic waves or ultrasonic waves for the purpose of particle detection. Accordingly, it is possible to facilitate maintenance of the irradiation device 71A. Furthermore, even when a plurality of pad opening portions 101 are formed on a polishing surface 102, it is possible to perform particle detection on the polishing liquid L1 that is introduced from all the pad opening portions 101 by a smaller number of irradiation devices 71A, for example, one.

### Modification 2-3

FIG. 11 is a sectional view schematically showing a particle detection system 700D according to the present modification. The particle detection system 700D according to the present modification differs from the particle detection system 700B of modification 2-1 described above in that it includes a movable member 60B instead of the movable member 60, and includes a detector 72A instead of the detector 72. The movable member 60B includes the detector 72A and is configured so that the detector 72A detects a signal such as electromagnetic waves from a polishing liquid L1 located between a table window portion 320 and a pad opening portion 101. The polishing liquid L1 is irradiated with electromagnetic waves or the like by an irradiation device 71 arranged below the table window portion 320.

In the present modification, the movable member 60B includes the detector 72A that detects a signal related to a size of particles P1 from the polishing liquid L1. Accordingly, it is possible to facilitate maintenance of the detector 72A. Furthermore, even when a plurality of pad opening portions 101 are formed on a polishing surface 102, it is possible to perform particle detection on the polishing liquid L1 that is introduced from all the pad opening portions 101 by a smaller number of detectors 72A, for example, one.

### Modification 2-4

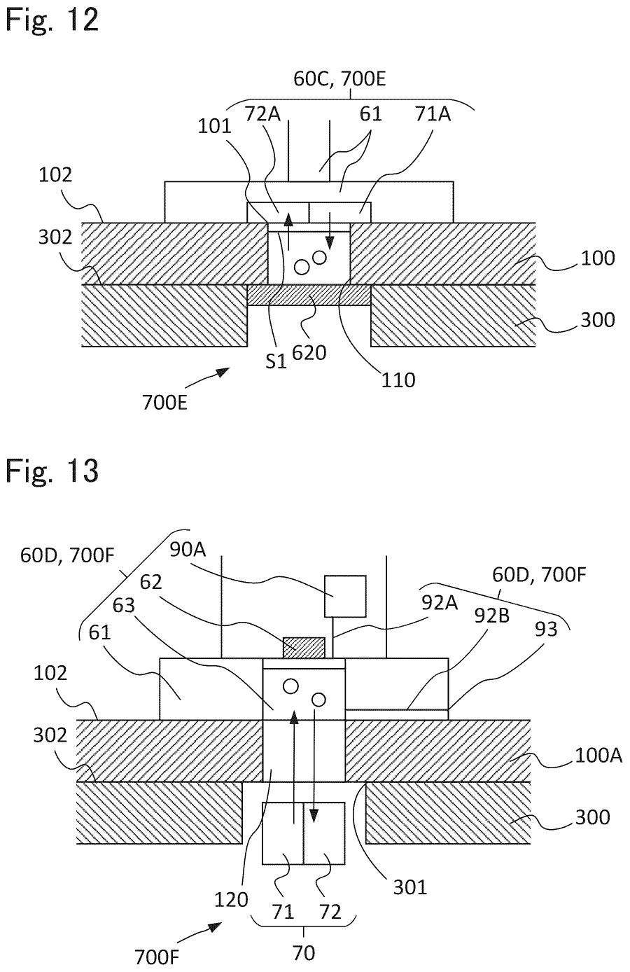

FIG. 12 is a sectional view schematically showing a particle detection system 700E according to the present modification. The particle detection system 700E according to the present modification differs from the particle detection system 700B of modification 2-1 described above in that it includes a movable member 60C instead of the movable member 60 and includes an irradiation device 71A and a detector 72A respectively instead of the irradiation device 71 and the detector 72. The movable member 60C includes the irradiation device 71A and the detector 72A. The irradiation device 71A is configured to irradiate a polishing liquid L1 located between a table window portion 320 and a pad opening portion 101 with electromagnetic waves or the like so that the detector 72A detects a signal such as electromagnetic waves from the polishing liquid L1. A polishing table 30 preferably includes a light blocking member 620 that defines a surface on a side where a polishing pad 100 is placed. The light blocking member 620 is preferably selected appropriately from those with high light absorption properties so as to suppress effects of reflection light and the like, according to the measurement methods.

In the present modification, the movable member 60C includes the irradiation device 71A that irradiates the polishing liquid L1 with electromagnetic waves or ultrasonic waves for the purpose of particle detection, and the detector 72A that detects a signal related to the size of particles P1 from the polishing liquid L1. Accordingly, even when the measurement unit 70 or the like is not included on a polishing table 30 side, it is possible to perform particle detection by installing the movable member 60C in a polishing apparatus 1000.

### Modification 3-1

FIG. 13 is a sectional view schematically showing a particle detection system 700F of the present modification. The particle detection system 700F of the present modification includes a measurement unit 70 arranged below a table opening portion 301, and a movable member 60D. The movable member 60D includes a movable member body 61, a recessed portion 63, a light blocking member 62, a pump 90A, and flow paths 92A and 92B. The pump 90A is fluidly connected to the recessed portion 63 via the flow path 92A so as to be able to suck. The flow path 92B fluidly connects the recessed portion 63 and an opening 93 formed in an outer surface of the movable member 60D, and is configured to be able to suck a polishing liquid L1 into the recessed portion 63 from the opening 93 by the pump 90A when the movable member 60D is arranged on a polishing surface 102. The opening 93 is formed at a position lower than a height of a liquid level of the polishing liquid L1 on the polishing surface 102 that is normally expected. A polishing pad 100A includes a pad window portion 120 that penetrates through the polishing pad 100A having a sheet shape in a thickness direction.

The recessed portion 63 functions as a polishing liquid accommodation section that accommodates the polishing liquid L1 for the purpose of particle detection. In the illustrated example, the recessed portion 63 is formed in a bottom surface of the movable member 60D, and is defined by the movable member body 61. The polishing pad 100A is placed on a pad disposing surface 302 so that the table opening portion 301 and the pad window portion 120 overlap each other, along the pad disposing surface 302. By control of a control device 900, the movable member 60D is arranged on the polishing surface 102 so that the recessed portion 63 and the pad window portion 120 overlap each other, along the polishing surface 102. By suction of the pump 90A, the polishing liquid L1 on the polishing surface 102 is introduced into a region surrounded by the recessed portion 63 and the polishing surface 102, and particle detection is performed on the introduced polishing liquid L1. In the particle detection, electromagnetic waves or the like emitted by an irradiation device 71 are incident on the polishing liquid L1 in the recessed portion 63 through the pad window portion 120. Signals such as electromagnetic waves from the polishing liquid L1 in the recessed portion 63 are detected by a detector 72 through the pad window portion 120. The movable member 60D may include a chamber that accommodates the polishing liquid L1 instead of the recessed portion 63, and in this case, the chamber is configured so that electromagnetic waves or the like can be incident or emitted via a window portion.

The movable member 60D according to the present modification includes the recessed portion 63, and the pump 90A for introducing the polishing liquid L1 into the recessed portion 63. Accordingly, after particle detection, discharge of the polishing liquid L1 is easy. A polishing apparatus 1000 of the present modification includes the detector 72 that performs detection of a signal related to a size or the like of particles P1 from the polishing liquid L1 that is positioned on the polishing surface 102. Accordingly, it is possible to suppress a risk of being unable to perform accurate detection as a result of the state of the polishing liquid L1 changing when collecting the polishing liquid L1.

### Modification 3-2

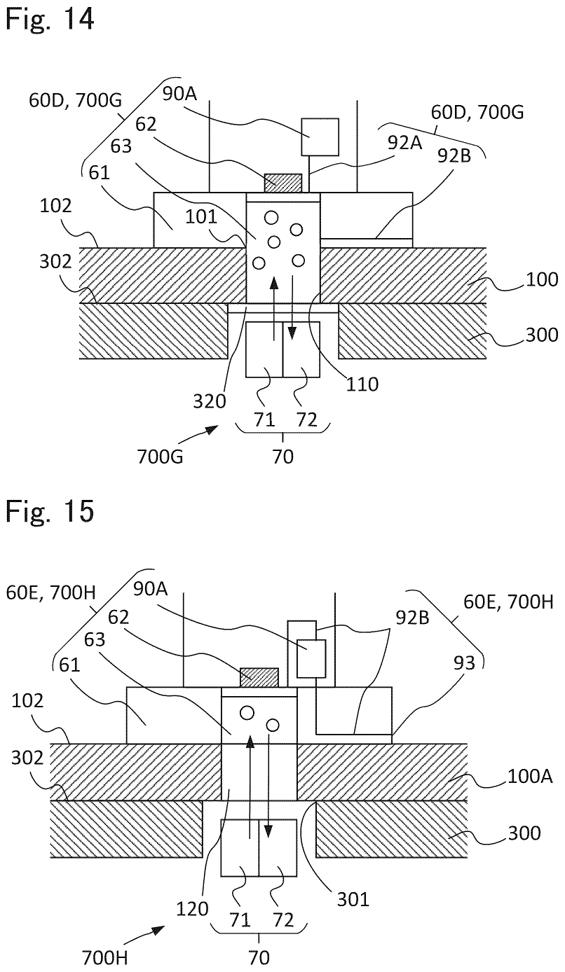

FIG. 14 is a sectional view schematically showing a particle detection system 700G according to the present modification. The particle detection system 700G according to the present modification has a substantially same configuration as the particle detection system 700F of the aforementioned modification, but differs from the particle detection system 700F in that a polishing table 30 includes a table window portion 320 on a side where a polishing pad 100 is placed, of the polishing table 30. In the present modification, a polishing pad 100 including a pad opening portion 101 may be located on a pad disposing surface 302. In this case, the polishing pad 100 is placed on the pad disposing surface 302 so that the pad opening portion 101 and the table window portion 320 overlap each other along the pad disposing surface 302. A movable member 60D is arranged on a polishing surface 102 so that the pad opening portion 101 and a recessed portion 63 overlap each other along the polishing surface 102. A polishing liquid L1 is introduced into a region including the recessed portion 63 and a through-hole 110 of the polishing pad 100 by a pump 90A, and particle detection is performed on the introduced polishing liquid L1. The recessed portion 63 and the through-hole 110 function as a polishing liquid accommodation section that accommodates the polishing liquid L1 for the purpose of particle detection. In the particle detection, electromagnetic waves or the like emitted by an irradiation device 71 are incident on the polishing liquid L1 through the table window portion 320. Signals such as electromagnetic waves from the polishing liquid L1 in the recessed portion 63 and the through-hole 110 are detected by a detector 72 through the table window portion 320.

In the present modification, an amount of the polishing liquid L1 that is a target of particle detection can be increased more, and particle detection can be performed more reliably, than in modification 3-1 described above.

### Modification 3-3

FIG. 15 is a sectional view schematically showing a particle detection system 700H according to the present modification. The particle detection system 700H according to the present modification has a substantially same configuration as the particle detection system 700F of modification 3-1 described above, but differs from the particle detection system 700F in that it includes a movable member 60E instead of the movable member 60D. In the movable member 60E, a pump 90A is arranged in a flow path 92B that fluidly connects a recessed portion 63 and an opening 93 formed in an outer surface of the movable member 60E. The pump 90A is configured to suck a polishing liquid L1 on a polishing surface 102 to introduce it into the recessed portion 63.

### Modification 3-4

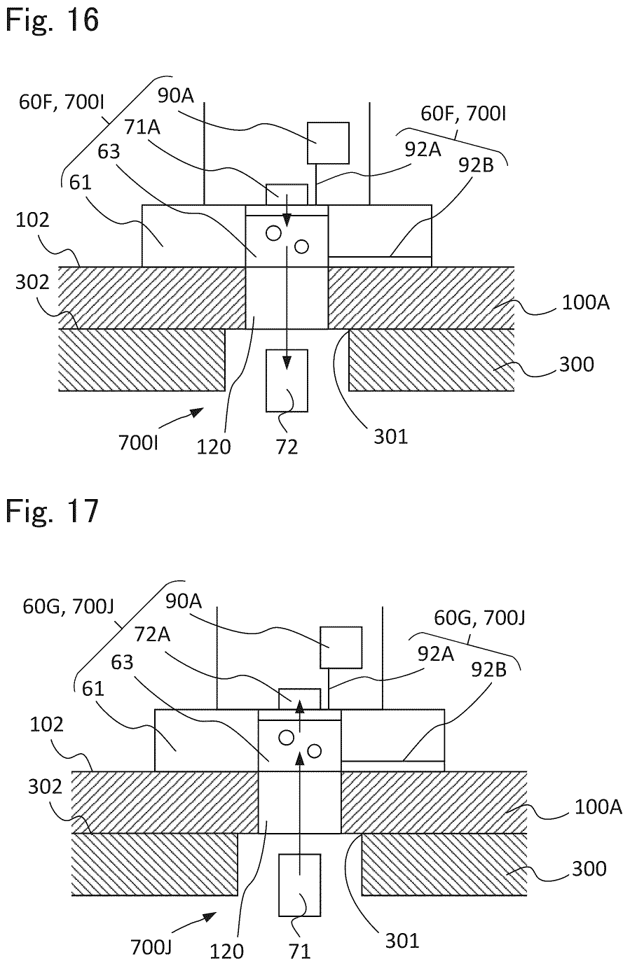

FIG. 16 is a sectional view schematically showing a particle detection system 700I according to the present modification. The particle detection system 700I according to the present modification differs from the particle detection system 700B of modification 3-1 described above in that it includes a movable member 60F instead of the movable member 60D, and includes an irradiation device 71A instead of the irradiation device 71. The movable member 60F includes the irradiation device 71A, and the irradiation device 71A is configured to irradiate a polishing liquid L1 located in a region surrounded by a recessed portion 63 and a polishing surface 102 with electromagnetic waves or the like. Signals such as electromagnetic waves from the polishing liquid L1 pass through a pad window portion 120 of a pad 100A, and are detected by a detector 72 arranged below a table opening portion 301. Note that as in the example of FIG. 14, the irradiation device 71A may be configured to irradiate the polishing liquid L1 positioned in the recessed portion 63 and a through-hole 110 by using a pad 100 having the through-hole 110 instead of the pad 100A. The same applies to modifications 3-5 and 3-6 as follows.

### Modification 3-5

FIG. 17 is a sectional view schematically showing a particle detection system 700J according to the present modification. The particle detection system 700J according to the present modification differs from the particle detection system 700F of modification 3-1 described above in that it includes a movable member 60G instead of the movable member 60D, and includes a detector 72A instead of the detector 72. The movable member 60G includes the detector 72A, and the detector 72A is configured to detect signals such as electromagnetic waves from a polishing liquid L1 located in a region surrounded by a recessed portion 63 and a polishing surface 102. The polishing liquid L1 is irradiated with electromagnetic waves or the like by an irradiation device 71 arranged below a table opening portion 301.

### Modification 3-6

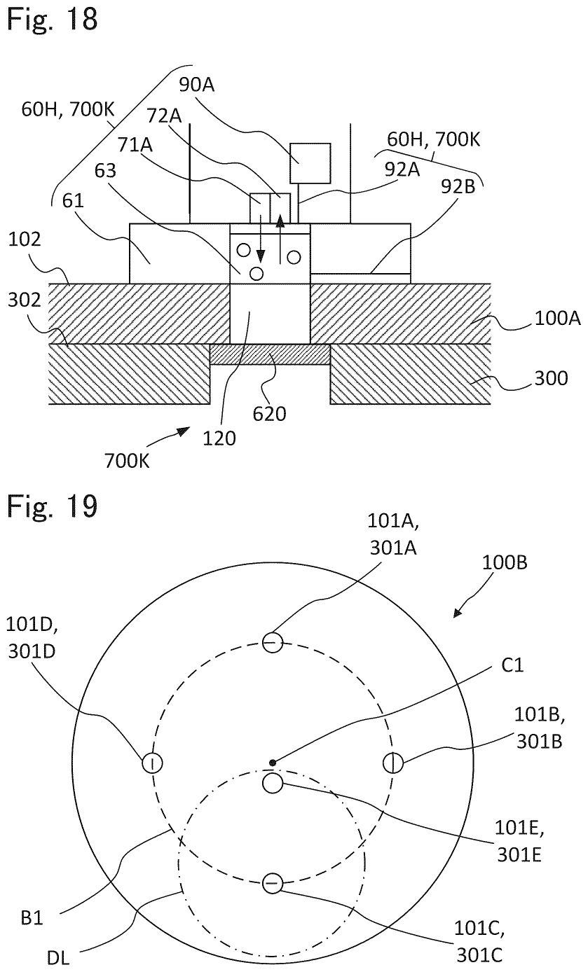

FIG. 18 is a sectional view schematically showing a particle detection system 700K according to the present modification. The particle detection system 700K according to the present modification differs from the particle detection system 700F of modification 3-1 described above in that it includes a movable member 60H instead of the movable member 60, and includes an irradiation device 71A and a detector 72A respectively instead of the irradiation device 71 and the detector 72. The movable member 60H includes the irradiation device 71A and the detector 72A. The irradiation device 71A is configured to irradiate a polishing liquid L1 located in a region surrounded by a recessed portion 63 and a polishing surface 102 with electromagnetic waves or the like, and the detector 72A is configured to detect signals such as electromagnetic waves from the polishing liquid L1. From the viewpoint of suppressing an adverse effect due to reflection light or the like, a polishing table 30 preferably includes a light blocking member 620 that defines a surface on a side where a polishing pad 100A is placed. If it is possible to perform particle detection with desired precision by properly reducing noise or the like, the polishing table 30 may not include the light blocking member 620, and the polishing pad 100A may not include a pad window portion 120.

### Modification 4

FIG. 19 is a plan view showing a polishing pad 100B according to the present modification. The polishing pad 100B includes a plurality of pad opening portions 101A, 101B, 101C, 101D, and 101E. A polishing table 30 includes a plurality of table opening portions 301A, 301B, 301C, 301D, and 301E so that these table opening portions respectively overlap the plurality of pad opening portions 101A, 101B, 101C, 101D, and 101E.

The polishing pad 100B is configured to be placed so that a center position C1 is aligned with a position of a rotation axis of the polishing table 30. In the polishing pad 100B, four or more pad opening portions 101 are preferably located in different positions in a circumferential direction with respect to the center position C1. Furthermore, the polishing table 30 preferably includes four or more table opening portions 301 that are located in different positions in a circumferential direction with respect to the rotation axis of the polishing table 30. Accordingly, even if the state of the polishing liquid L1 is uneven in the circumferential direction on the polishing surface 102, abnormality in the polishing liquid L1 can be detected more reliably. From a same viewpoint, the plurality of pad opening portions 101 are preferably positioned rotationally symmetrically about an axis that passes through the center position C1 and is perpendicular to the polishing pad 100B. In the illustrated example, the plurality of pad opening portions 101A, 101B, 101C and 101D are located at equal intervals in the circumferential direction along a circle shown by a broken line B1.

FIG. 19 schematically shows an approximate position where a substrate WF is placed during polishing, on the polishing pad 100B, by a circle DL of an alternate long and short dash line. The pad opening portions 101A, 101B, 101C, and 101D are positioned in positions where a central portion of the substrate WF passes on the polishing pad 100B. The pad opening portion 101E is positioned at a position that is closer to the center position C1 of the polishing pad 100B than the pad opening portion 101A and the like, and is positioned at a position where a periphery portion of the substrate WF passes. In this way, the plurality of pad opening portions 101 are preferably located in a plurality of positions corresponding to a plurality of positions different from each other on the substrate WF. Likewise, the plurality of table opening portions 301 are preferably located in a plurality of positions corresponding to the plurality of positions different from each other on the substrate WF. Accordingly, it is possible to detect abnormality of the polishing liquid L1 so as to avoid an adverse effect due to the polishing liquid L1, throughout a wide range of the substrate WF. The particle detection system 700 may include a plurality of measurement units 70 that correspond to the plurality of pad opening portions 101 and the plurality of table opening portions 301 respectively. Note that the number and positions of the pad opening portions 101 in the polishing pad 100, and the number and positions of the table opening portions 301 in the polishing table 30 are not limited to the contents of the present modification, and any number of pad opening portions 101 and table opening portions 301, one or more, may be provided in any position.

### Modification 5

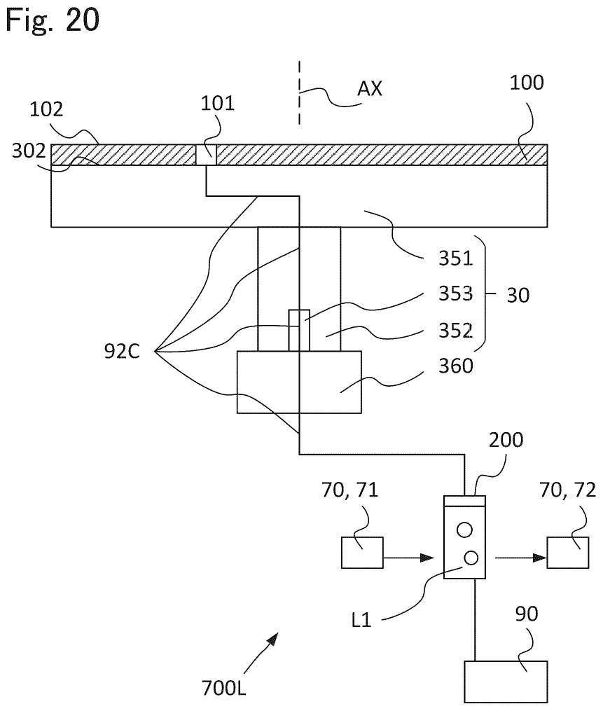

FIG. 20 is a sectional view schematically showing a particle detection system 700L of the present modification. The particle detection system 700L of the present modification has a substantially same configuration as the particle detection system 700A of modification 1 described above, but differs from the particle detection system 700A in that it has a flow path 92C that extends to an outside of a polishing table 30 through an inside of the polishing table 30 from a pad disposing surface 302, instead of the flow path 92. As shown in FIG. 20, the polishing table 30 can include a polishing table body 351, a table shaft 352, a rotary joint 353, and a table drive device 360 including a motor or the like. The table shaft 352 supports the polishing table body 351, and extends along a rotation axis AX so as to surround the rotation axis AX of the polishing table 30. The table shaft 352 is rotatably supported by the table drive device 360. The flow path 92C can pass through an inside of the polishing table body 351, the table shaft 352, and the rotary joint 353 from the pad disposing surface 302 and can be introduced into a chamber 200 outside the polishing table 30. A signal from a polishing liquid L1 in an inside of the chamber 200 that is a detection position is detected by a detector 72. In the rotary joint 353, a portion of the flow path 92C that rotates is fluidly connected to another portion of the flow path 92C rotatably. More specifically, the rotary joint 353 fluidly connects the portion of the flow path 92C that rotates integrally with the polishing table body 351 and the table shaft 352, and the portion that is in an outside of the polishing table body 351 and the table shaft 352 and does not rotate integrally with the polishing table body 351 and the like, regardless of presence or absence of the rotation. Since the flow path 92C can be longer than the case in which the chamber 200 is located in the polishing table 30, flow of the polishing liquid L1 may be promoted by a pump 90 in any position.

In the present modification, the flow path 92C extends to the detection position in an outside of the polishing table 30, and the detector 72 is configured to perform detection of a signal related to a size of particles P1 from the polishing liquid L1 that is located at the detection position. At least one of an irradiation device 71, the detector 72, and the chamber 200 can be arranged in the outside of the polishing table 30. By the configuration like this, it is possible to install a measurement unit 70 without any restrictions on the size of the space in which the measurement unit 70 is arranged or the like, and it is possible to install the measurement unit 70 with higher performance and dispose a plurality of detectors 72 at desired positions.

### Modification 6

In the aforementioned embodiment, the detector 72 may perform detection of a signal related to at least one of the size, shape, dispersibility, and optical property of the particles P1 without being limited to particle detection and particle determination concerning the size of the particles P1. In this case, the control device 900 can perform particle determination to determine whether the polishing liquid L1 on which particle detection is performed contain particles that damage the substrate WF, based on particle data indicating at least one of the size, shape, dispersibility and optical property of the particles P1 obtained based on the signal detected by the detector 72, and correspondence information indicating correspondence of at least one of the size, shape, dispersibility, and optical property of the particles of the polishing liquid, and whether the particles are the particles that damage the substrate.

### Modification 6-1

In the present modification, an example in which a detector 72 performs, as particle detection, detection of a signal related to a shape of particles P1 will be described. In this case, a control device 900 can perform particle determination, based on particle data indicating the shape of the particles P1 obtained based on the signal, and correspondence information indicating correspondence of the shape of particles of a polishing liquid, and whether the particles are particles that damage a substrate. The signal related to the shape of the particles P1 is a signal from which the particle data indicating the shape of the particles P1 can be obtained by analyzing the signal.

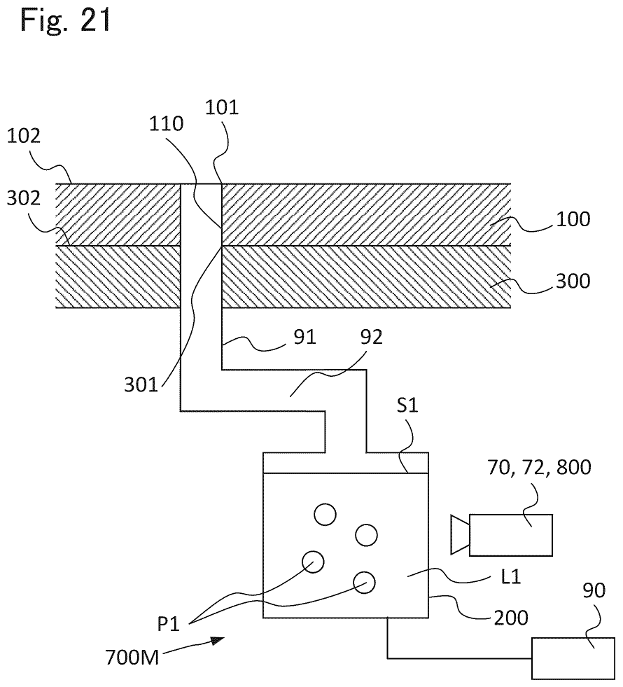

FIG. 21 is a schematic view showing a particle detection system 700M according to the present modification. The particle detection system 700M of the present modification includes a detector 72 including an image capturing device 800, and the image capturing device 800 is configured to capture an image of a polishing liquid L1. In the illustrated example, the image capturing device 800 is configured to capture the image of the polishing liquid L1 positioned in a chamber 200 that communicates with a pad opening portion 101. The image capturing device 800 may capture an image of the polishing liquid L1 in a flow path 91 or the like. The image capturing device 800 may be a camera that can photoelectrically convert visible light, or may be an infrared camera.

A control device 900 generates particle data indicating a shape of particles from image data obtained by capturing the image of the polishing liquid L1 by the image capturing device 800. In the image data, for example, positions of pixels, and intensities of received light are associated with each other. The control device 900 processes the image data, and derives, from the image of the polishing liquid L1, a shape of the particles P1 contained in the polishing liquid L1, in particular, a characteristic value indicating the shape of the particles P1. The control device 900 can cause a storage device 930 or the like to store the characteristic value indicating the shape of the particles P1 as the particle data. The characteristic value is not particularly limited if only it affects how the particles are likely to damage the substrate. The control device 900 performs particle determination based on the particle data thus obtained and the correspondence information. The correspondence information can indicate a numerical value range of the characteristic value indicating the shape of the particles to be particles that damage the substrate. The correspondence information can include, for example, a threshold value of the characteristic value indicating the shape of the particles, and the control device 900 can perform particle determination based on whether or not the characteristic value indicating the shape of the particles P1 is the threshold value or more.

### Modification 6-2

In the present modification, an example in which a detector 72 performs detection of a signal related to dispersibility of particles P1 in a polishing liquid L1 as particle detection is described. In this case, a control device 900 can perform particle determination based on particle data indicating dispersibility of the particles P1 obtained based on the signal, and correspondence information indicating correspondence of dispersibility of particles of the polishing liquid, and whether the particles are particles that damage a substrate. The signal related to the dispersibility of the particles P1 is a signal from which particle data indicating the dispersibility of the particles P1 can be obtained by analyzing the signal. In the present modification, particle detection can be performed by the aforementioned particle detection system 700M.

A control device 900 generates the particle data indicating the dispersibility of the particles P1 from image data obtained by capturing an image of the polishing liquid L1 by an image capturing device 800. The control device 900 processes the image data, derives positions of a plurality of particles P1 contained in the polishing liquid L1 from the image of the polishing liquid L1, and derives a characteristic value indicating dispersibility of the particles P1 based on distribution of the positions. The control device 900 can cause a storage device 930 or the like to store a characteristic value indicating the dispersibility of the particles P1 as the particle data. The characteristic value is not particularly limited if only it affects susceptibility of the substrate to damage by particles. The characteristic value may be an amount of particles P1 that are sinking. For example, when the particles P1 are distributed relatively uniformly in the polishing liquid L1, it is conceivable that the particles P1 are small or light enough to be dispersed in the polishing liquid L1 and a risk of damaging the substrate WF is relatively low. When the particles P1 are sinking, or localized, the risk of damaging the substrate WF can be considered as relatively high. The control device 900 performs particle determination based on the particle data thus obtained, and correspondence information. The correspondence information can indicate a numerical value range of the characteristic value indicating the dispersibility of particles, in which they become particles that damage the substrate. The correspondence information can contain, for example, a threshold value of the characteristic value indicating the dispersibility of the particles P1, and the control device 900 can perform particle determination based on whether or not the characteristic value indicating the dispersibility of the particles P1 is equal to or larger than the threshold value.

### Modification 6-3

In the present modification, an example in which a detector 72 performs detection of a signal related to an optical property of the particles P1 as particle detection is described. In this case, a control device 900 can perform particle determination based on particle data indicating the optical property of the particles P1 obtained based on the signal, and correspondence information indicating correspondence of the optical property of the particles of the polishing liquid and whether the particles are particles that damage the substrate. The signal related to the optical property of the particles P1 is a signal from which particle data indicating the optical property of the particles P1 can be acquired by analyzing the signal. In the present modification, particle detection can be performed by the aforementioned particle detection system 700M.

A control device 900 generates particle data indicating the optical property of the particles P1 from image data obtained by capturing an image of a polishing liquid L1 by an image capturing device 800. The optical property can be, for example, a wavelength of light reflected or scattered in the particles P1, in other words, a color of surfaces of the particles P1, or reflectivity of the surfaces of the particles P1. The control device 900 processes the image data, and derives the above-described wavelength, the reflectivity, or the like of the surfaces of the particles P1 contained in the polishing liquid L1 as a characteristic value indicating the optical property of the particles P1, from the image of the polishing liquid L1. The control device 900 can cause a storage device 930 or the like to store the characteristic value indicating the optical property of the particles P1 as the particle data. The characteristic value is not particularly limited if only it affects susceptibility of the substrate to damage by the particles. For example, a state of the surfaces of the particles P1 differs depending on a color or the reflectivity of the surface of the particles P1, and the risk of damaging the substrate WF may change. The control device 900 performs particle determination based on the particle data thus obtained and the correspondence information. The correspondence information can indicate a numerical value range of the characteristic value indicating the optical property of the particles, in which the particles become particles that damage the substrate. The correspondence information can contain, for example, a threshold value of the characteristic value indicating the optical property of the particles P1, and the control device 900 can perform particle determination based on whether or not the characteristic value indicating the optical property of the particles P1 is equal to or larger than the threshold value.

The embodiments described above can also be described as the following modes. [Mode 1] According to mode 1, a polishing apparatus is proposed, the polishing apparatus is a polishing apparatus including a polishing table for supporting a polishing pad having a polishing surface, a polishing head for holding a substrate, a polishing liquid supply device for supplying a polishing liquid to between the polishing pad and the substrate, and a control device, and performing polishing of the substrate by bringing the polishing pad and the substrate into contact with each other in presence of the polishing liquid, the polishing apparatus further including a detector that performs detection of a signal related to at least one of a size, shape, dispersibility, and optical property of particles, from the polishing liquid positioned on the polishing surface, or the polishing liquid positioned in a flow path or a chamber that communicates with a pad opening portion formed in the polishing pad, wherein the control device is configured to perform particle determination of determining whether the polishing liquid on which the detection has been performed contains particles that damage the substrate, based on particle data indicating at least one of the size, shape, dispersibility, and optical property of the particles obtained based on the signal detected by the detector, and correspondence information indicating correspondence of at least one of the size, shape, dispersibility, and optical property of particles of the polishing liquid, and whether the particles are the particles that damage the substrate. According to mode 1, it is possible to provide the polishing apparatus capable of evaluating the state of the polishing liquid more efficiently or more precisely while suppressing change in the state of the polishing liquid, concerning the polishing liquid after being served on the polishing surface.

[Mode 2] According to mode 2, in mode 1, the polishing table includes a table opening portion that is arranged to communicate with the pad opening portion, the polishing apparatus further includes at least one of a flow path and a chamber that communicate with the table opening portion, and the detector is configured to perform the detection on the polishing liquid that is positioned in the flow path or the chamber. According to mode 2, the polishing liquid can be located at the detection position quickly, and polishing conditions are easily adjusted by blocking light from the outside of the polishing apparatus.

[Mode 3] According to mode 3, in mode 2, the polishing apparatus further includes a pump that is connected to be able to suck the flow path or the chamber. According to mode 3, it is possible to promote introduction of the polishing liquid into the flow path or the chamber from the polishing surface, and discharge of the polishing liquid from the flow path or the chamber, and it is possible to more reliably perform particle detection.

[Mode 4] According to mode 4, in mode 2 or 3, a minimum diameter of the table opening portion is equal to or more than 1 mm. According to mode 4, the polishing liquid is easily introduced into the flow path or the chamber.

[Mode 5] According to mode 5, in any one of modes 2 to 4, a maximum diameter of the table opening portion is equal to or less than 10 mm. According to mode 5, it is possible to suppress a risk of the table opening portion adversely affecting efficiency or uniformity of polishing.

[Mode 6] According to mode 6, in any one of modes 2 to 5, the table opening portion is positioned so that the substrate covers the table opening portion during the polishing, in the polishing table. According to mode 6, it is possible to efficiently detect polishing dust or the like that is generated by polishing of the substrate.

[Mode 7] According to mode 7, in any one of modes 2 to 6, a shutter for blocking light from the pad opening portion, or for preventing inflow of the polishing liquid from the pad opening portion is further included. According to mode 7, it is possible to reduce noise caused by light and perform particle detection more accurately.

[Mode 8] According to mode 8, in mode 1, the detector is configured to perform the detection on the polishing liquid that is positioned in a through-hole formed in the polishing pad. According to mode 8, it is possible to prevent efficiency or uniformity of polishing from being reduced by the table opening portion.

[Mode 9] According to mode 9, in any one of modes 2 to 7, the detector performs the detection of the signal from the polishing liquid that is positioned in the flow path or the chamber that communicates with the pad opening portion, and the detector is positioned below a surface on which the polishing pad is placed in the polishing table. According to mode 9, it is possible to prevent the detector from being positioned in the region above the polishing surface, and it is possible to dispose more members in the region. Furthermore, it is possible to more reliably introduce the polishing liquid into the flow path or the chamber by using gravity or the like.

[Mode 10] According to mode 10, in any one of modes 1 to 9, an irradiation device that irradiates the polishing liquid with electromagnetic waves or ultrasonic waves for a purpose of the detection is further included, wherein the detector performs the detection of the electromagnetic waves or the ultrasonic waves that pass through the polishing liquid, or electromagnetic waves or ultrasonic waves that are generated by scattering or reflection of the electromagnetic waves or the ultrasonic waves in the polishing liquid, and the irradiation device is positioned below a surface where the polishing pad is placed in the polishing table. According to mode 10, it is possible to prevent the irradiation device from being positioned in the region above the polishing surface, and it is possible to dispose more members in the region.

[Mode 11] According to mode 11, in any one of modes 1 to 10, a movable member that is configured to be movable between an upper side of the polishing surface, and a retraction position at a side of the polishing table is further included, wherein the movable member includes at least one of the detector, and an irradiation device that irradiates the polishing liquid with electromagnetic waves or ultrasonic waves for a purpose of the detection. According to mode 11, it is possible to facilitate maintenance of the irradiation device or the detector. Furthermore, even when a plurality of pad opening portions are formed on the polishing surface, it is possible to perform particle detection with respect to all the pad opening portions by a smaller number of irradiation devices or detectors.

[Mode 12] According to mode 12, in any one of modes 2 to 7, and 9 and 10, the flow path extends to a detection position in an outside of the polishing table, and the detector is configured to perform the detection of the signal from the polishing liquid that is in the detection position. According to mode 12, it is possible to install the irradiation device or the detector without restrictions on the size or the like of the space where the irradiation device or the detector is arranged, and it is possible to install the irradiation device or the detector with higher performance, or dispose a plurality of detectors at desired positions with respect to the polishing liquid.

[Mode 13] According to mode 13, in any one of modes 1 to 12, the control device is configured to perform the detection by the detector (1) when the polishing liquid is supplied to the polishing pad, (2) while the polishing is being performed, or (3) when the polishing liquid remains on the polishing pad after end of the polishing. According to mode 13, it is possible to prevent the substrate from being damaged or polishing that is different from what is expected from being performed by performing particle detection when an effect of the polishing liquid on polishing is large, or when cleaning or replacement of consumables is easily performed.

[Mode 14] According to mode 14, in any one of modes 1 to 13, the detection and acquisition of the particle data are performed by at least one of a laser diffraction/scattering method, a dynamic light scattering method, an ultrasonic attenuation method, zeta potential measurement, spectroscopic measurement, and analysis of an image obtained by capturing the image of the polishing liquid. According to mode 14, it is possible to more reliably detect the particles that damage the substrate in the polishing liquid by taking advantage of the characteristics of these measurement methods.

[Mode 15] According to mode 15, in any one of modes 1 to 14, the control device is configured to perform at least one of issuing of warning, stop of the polishing, and cleaning of the polishing surface, when it is determined that the polishing liquid on which the detection is performed contains particles that damage the substrate, based on the particle determination. According to mode 15, it is possible to more reliably prevent the substrate WF from being damaged, or polishing that is different from what is expected from being performed based on the result of particle detection.

[Mode 16] According to mode 16, in any one of modes 1 to 15, the detector includes an image capturing device that captures an image of the polishing liquid. According to mode 16, it is possible to perform particle detection by the simple configuration. Furthermore, it is possible to perform particle detection not only when polishing is not performed, but also during polishing.

[Mode 17] According to mode 17, in any one of modes 1 to 16, the polishing apparatus performs the polishing of the substrate by bringing the polishing pad and the substrate into contact with each other and rotationally moving them relative to each other in presence of the polishing liquid. According to mode 17, it is possible to perform polishing more efficiently or more uniformly.

[Mode 18] According to mode 18, a substrate processing apparatus is proposed, and the substrate processing apparatus includes the polishing apparatus according to any one of modes 1 to 17. According to mode 18, it is possible to provide the substrate processing apparatus that can process a substrate more efficiently, and reduces the risk of a substrate being damaged or polishing that differs from what is expected being performed.

[Mode 19] According to mode 19, a polishing method is proposed, and the polishing method is a polishing method for performing polishing of a substrate by bringing a polishing pad and the substrate into contact with each other in presence of a polishing liquid by a polishing apparatus including a polishing table for supporting the polishing pad having a polishing surface, a polishing head for holding the substrate, and a polishing liquid supply device for supplying the polishing liquid to between the polishing pad and the substrate, and includes performing detection of a signal related to at least one of a size, shape, dispersibility, and optical property of particle, from the polishing liquid positioned on the polishing surface, or the polishing liquid positioned in a flow path or a chamber that communicates with a pad opening portion formed in the polishing pad, and performing particle determination to determine whether the polishing liquid on which the detection has been performed contains particles that damage the substrate, based on particle data indicating at least one of the size, shape, dispersibility, and optical property of the particles obtained based on the signal detected by a detector, and correspondence information indicating correspondence of at least one of the size, shape, dispersibility, and optical property of particles of the polishing liquid, and whether the particles are the particles that damage the substrate. According to mode 19, it is possible to evaluate a state of the polishing liquid more efficiently or more precisely while suppressing change in the state of the polishing liquid, concerning the polishing liquid after being served on the polishing surface.

[Mode 20] According to mode 20, a determination device is proposed, the determination device is a determination device that determines a state of a polishing liquid in a polishing apparatus, wherein the polishing apparatus includes a polishing table for supporting a polishing pad having a polishing surface, a polishing head for holding a substrate, and a polishing liquid supply device for supplying the polishing liquid to between the polishing pad and the substrate, and performs polishing of the substrate by bringing the polishing pad and the substrate into contact with each other in presence of the polishing liquid, the polishing apparatus further includes a detector that performs detection of a signal related to at least one of a size, shape, dispersibility, and optical property of particles, from the polishing liquid positioned on the polishing surface, or the polishing liquid positioned in a flow path or a chamber that communicates with a pad opening portion formed in the polishing pad, and the determination device is configured to perform particle determination to determine whether the polishing liquid on which the detection has been performed contains particles that damage the substrate, based on particle data indicating at least one of the size, shape, dispersibility, and optical property of the particles obtained based on the signal detected by the detector, and correspondence information indicating correspondence of at least one of the size, shape, dispersibility, and optical property of the particles of the polishing liquid, and whether the particles are the particles that damage the substrate. According to mode 20, it is possible to evaluate the state of a polishing liquid more efficiently or more precisely while suppressing change in the state of the polishing liquid, concerning the polishing liquid after being served on the polishing surface.

Although the embodiments of the present invention have been described above, the described embodiments are for the purpose of facilitating the understanding of the present invention and are not intended to limit the present invention. The present invention may be modified and improved without departing from the spirit thereof, and the invention includes equivalents thereof. In addition, the embodiments and modifications can be arbitrarily combined, and the elements described in the claims and the specification can be arbitrarily combined or omitted within a range in which the above-mentioned problems are at least partially solved, or within a range in which at least a part of the advantages is achieved.

### REFERENCE SIGNS LIST

3, 3A, 3B, 3C, 3D polishing unit
10 substrate processing apparatus
30 polishing table
31 polishing head
32 polishing liquid supply device
60, 60A, 60B, 60C, 60D, 60E, 60F, 60G, 60H movable member
62, 620 light blocking member
63 recessed portion
70 measurement unit
71, 71A irradiation device
72, 72A, 72B detector
90, 90A pump
92, 92A 92B, 92C flow path
100, 100A, 100B polishing pad
101, 101A, 101B, 101C, 101D, 101E pad opening portion
102 polishing surface
110 through-hole
120 pad window portion
200 chamber
301, 301A, 301B, 301C, 301D, 301E table opening portion
302 pad disposing surface
320 table window portion
700, 700A, 700B, 700C, 700D, 700E, 700F, 700G, 700H, 700I, 700J, 700K, 700L, 700M particle detection system
800 image capturing device
900 control device
910 arithmetic unit
920 memory
930 storage device
1000 polishing apparatus
1100 polishing system
C1 center position of polishing pad
D10 diameter of pad opening portion
D11 minimum diameter of pad opening portion
D12 maximum diameter of pad opening portion
D30 diameter of table opening portion
D31 minimum diameter of table opening portion
D32 maximum diameter of table opening portion
L1 polishing liquid
P1 particle
WF substrate

What is claimed is:

1. A polishing apparatus, comprising:
a polishing table for supporting a polishing pad having a polishing surface;
a polishing head for holding a substrate;
a polishing liquid supply device for supplying a polishing liquid to between the polishing pad and the substrate; and
a control device, and
performing polishing of the substrate by bringing the polishing pad and the substrate into contact with each other in presence of the polishing liquid,
the polishing apparatus further comprising a detector that performs detection of a signal related to at least one of a size, shape, dispersibility, and optical property of particles, from the polishing liquid positioned on the polishing surface, or the polishing liquid positioned in a flow path or a chamber that communicates with a pad opening portion formed in the polishing pad, wherein
the control device is configured to perform particle determination of determining whether the polishing liquid on which the detection has been performed contains particles that damage the substrate, based on particle data indicating at least one of the size, shape, dispersibility, and optical property of the particles obtained based on the signal detected by the detector, and correspondence information indicating correspondence of at least one of the size, shape, dispersibility, and optical property of particles of the polishing liquid, and whether the particles are the particles that damage the substrate.

2. The polishing apparatus according to claim 1, wherein
the polishing table includes a table opening portion that is arranged to communicate with the pad opening portion,
the polishing apparatus further comprises at least one of a flow path and a chamber that communicate with the table opening portion, and
the detector is configured to perform the detection on the polishing liquid that is positioned in the flow path or the chamber.

3. The polishing apparatus according to claim 2, further comprising a pump that is connected to be able to suck the flow path or the chamber.

4. The polishing apparatus according to claim 2, wherein a minimum diameter of the table opening portion is equal to or more than 1 mm.

5. The polishing apparatus according to claim 2, wherein a maximum diameter of the table opening portion is equal to or less than 10 mm.

6. The polishing apparatus according to claim 2, wherein the table opening portion is positioned so that the substrate covers the table opening portion during the polishing, in the polishing table.

7. The polishing apparatus according to claim 2, further comprising a shutter for blocking light from the pad opening portion, or for preventing inflow of the polishing liquid from the pad opening portion.

8. The polishing apparatus according to claim 1, wherein the detector is configured to perform the detection for the polishing liquid that is positioned in a through-hole formed in the polishing pad.

9. The polishing apparatus according to claim 2,
wherein the detector performs the detection on the signal from the polishing liquid that is positioned in the flow path or the chamber that communicates with the pad opening portion, and
the detector is positioned below a surface on which the polishing pad is placed in the polishing table.

10. The polishing apparatus according to claim 1, further comprising an irradiation device that irradiates the polishing liquid with electromagnetic waves or ultrasonic waves for a purpose of the detection, wherein
the detector performs the detection of the electromagnetic waves or the ultrasonic waves that pass through the polishing liquid, or electromagnetic waves or ultrasonic waves that are generated by scattering or reflection of the electromagnetic waves or the ultrasonic waves in the polishing liquid, and
the irradiation device is positioned below a surface where the polishing pad is placed in the polishing table.

11. The polishing apparatus according to claim 1, further comprising a movable member that is configured to be movable between an upper side of the polishing surface, and a retraction position at a side of the polishing table, wherein
the movable member includes at least one of the detector, and an irradiation device that irradiates the polishing liquid with electromagnetic waves or ultrasonic waves for a purpose of the detection.

12. The polishing apparatus according to claim 1, wherein the flow path extends to a detection position in an outside of the polishing table, and the detector is configured to perform the detection of the signal from the polishing liquid that is in the detection position.

13. The polishing apparatus according to claim 1, wherein the control device is configured to perform the detection by the detector (1) when the polishing liquid is supplied to the polishing pad, (2) while the polishing is being performed, or (3) when the polishing liquid remains on the polishing pad after end of the polishing.

14. The polishing apparatus according to claim 1, wherein the detection and acquisition of the particle data are performed by at least one of a laser diffraction/scattering method, a dynamic light scattering method, an ultrasonic attenuation method, zeta potential measurement, spectroscopic measurement, and analysis of an image obtained by capturing the image of the polishing liquid.

15. The polishing apparatus according to claim 1, wherein the control device is configured to perform at least one of issuing of warning, stop of the polishing, and cleaning of the polishing surface, when it is determined that the polishing liquid on which the detection is performed contains particles that damage the substrate, based on the particle determination.

16. The polishing apparatus according to claim 1, wherein the detector includes an image capturing device that captures an image of the polishing liquid.

17. The polishing apparatus according to claim 1, wherein the polishing apparatus performs the polishing of the substrate by bringing the polishing pad and the substrate into contact with each other and rotationally moving them relative to each other in presence of the polishing liquid.

18. A substrate processing apparatus including the polishing apparatus according to claim 1.

19. A polishing method for performing polishing of a substrate by bringing a polishing pad and the substrate into contact with each other in presence of a polishing liquid by a polishing apparatus including
a polishing table for supporting the polishing pad having a polishing surface,
a polishing head for holding the substrate, and
a polishing liquid supply device for supplying the polishing liquid to between the polishing pad and the substrate, the method comprising:
performing detection of a signal related to at least one of a size, shape, dispersibility, and optical property of particles, from the polishing liquid positioned on the polishing surface, or the polishing liquid positioned in a flow path or a chamber that communicates with a pad opening portion formed in the polishing pad, and
performing particle determination to determine whether the polishing liquid on which the detection has been performed contains particles that damage the substrate, based on particle data indicating at least one of the size, shape, dispersibility, and optical property of the particles obtained based on the signal detected by a detector, and correspondence information indicating correspondence of the size of particles of the polishing liquid, and whether the particles are the particles that damage the substrate.

20. A determination device that determines a state of a polishing liquid in a polishing apparatus, wherein
the polishing apparatus
includes a polishing table for supporting a polishing pad having a polishing surface,
a polishing head for holding a substrate, and
a polishing liquid supply device for supplying the polishing liquid to between the polishing pad and the substrate, and
performs polishing of the substrate by bringing the polishing pad and the substrate into contact with each other in presence of the polishing liquid,
the polishing apparatus further includes a detector that performs detection of a signal related to at least one of a size, shape, dispersibility, and optical property of particles, from the polishing liquid positioned on the polishing surface, or the polishing liquid positioned in a flow path or a chamber that communicates with a pad opening portion formed in the polishing pad, and
the determination device is configured to perform particle determination to determine whether the polishing liquid on which the detection has been performed contains particles that damage the substrate, based on particle data indicating at least one of the size, shape, dispersibility, and optical property of the particles obtained based on the signal detected by the detector, and correspondence information indicating correspondence of at least one of the size, shape, dispersibility, and optical property of the particles of the polishing liquid, and whether the particles are the particles that damage the substrate.
